(19) United States
(12) Patent Application Publication
(10) Pub. No.: US 2026/0096157 A1
(43) Pub. Date: Apr. 2, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yuan Tsung TSAI, Tainan City (TW); Che Wei LIN, Chiayi City (TW); Huei Tang WANG, Tainan City (TW); Ying Ming WANG, Tainan City (TW); Syue Yi LIN, Kaohsiung City (TW); Sung-Hsin YANG, Tainan (TW); Ling-Sung WANG, Tainan City (TW)

(21) Appl. No.: 18/903,227

(22) Filed: Oct. 1, 2024

(51) Int. Cl. H01L 29/06; H01L 21/311; H01L 21/3213; H01L 29/423

(52) U.S. Cl. CPC H10D 62/102; H10D 64/514; H10D 64/518; H10D 64/519; H10P 50/28; H10P 50/71

(57) ABSTRACT

A high-voltage transistor includes an asymmetric gate dielectric layer and/or a gate structure that includes one or more asymmetric work function metal layers. The gate dielectric layer and/or the work function metal layer(s) are asymmetric in that the height of the gate dielectric layer and/or the height of the work function metal layer(s) on opposing sides of the gate structure are different. In particular, the height of the gate dielectric layer and/or the height of the work function metal layer(s) on a side of the gate structure facing the drain region of the high-voltage transistor are lower than the height of the gate dielectric layer and/or the height of the work function metal layer(s) on an opposing side of the gate structure facing the source region of the high-voltage transistor.

### BACKGROUND

A high-voltage transistor includes a transistor that is configured to operate at greater voltages (e.g., a high gate voltage, a high drain voltage) relative to medium voltage transistors and low voltage transistors, and a medium voltage transistor includes a transistor that is configured to operate at greater voltages (e.g., a high gate voltage, a high drain voltage) relative to low voltage transistors. The maximum voltages that can be endured (without being damaged) by medium voltage transistors may be lower than the maximum voltages that can be endured (without being damaged) by high-voltage transistors, and the maximum voltages that can be endured (without being damaged) by low voltage transistors are lower than the maximum voltages that can be endured (without being damaged) by medium voltage transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of a portion of an example semiconductor device described herein.

FIGS. 2A and 2B are diagrams of an example implementation of forming fin structures for high-voltage transistors in the device layer of the semiconductor device described herein.

FIG. 3 is a diagram of an example implementation of forming dummy gate structures for high-voltage transistors in the device layer of the semiconductor device described herein.

FIGS. 4A-4D are diagrams of an example implementation of forming source/drain regions for high-voltage transistors in the device layer of the semiconductor device described herein.

FIGS. 5A-5R are diagrams of an example implementation of a replacement gate process for high-voltage transistors in the device layer of the semiconductor device described herein.

FIGS. 6A-6F are diagrams of an example implementation of a gate trimming process for high-voltage transistors in the device layer of the semiconductor device described herein.

FIG. 7 is a diagram of an example implementation of a contact formation process for high-voltage transistors in the device layer of the semiconductor device described herein.

FIG. 8 is a diagram of an example of a depletion region of a high-voltage transistor of the semiconductor device described herein.

FIG. 9 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

High-voltage transistors and medium voltage transistors may be used in applications such as integrated circuit (IC) drivers, power ICs, shifter circuits, image sensors, power management, radio frequency (RF) power amplifiers, display driver ICs (DDICs), bipolar complementary metal oxide semiconductor (CMOS) diffused metal oxide semiconductor (DMOS) ICs (BCD ICs), and/or image signal processing (ISP) ICs, among other examples.

In some cases, high-voltage transistors may be susceptible to performance drawbacks such as current leakage and/or parasitic capacitance, among other examples. Current leakage can occur in a high-voltage transistor in the form of gate-induced drain leakage (GIDL). GIDL is a form of sub-threshold current leakage that occurs between a source and a drain of a high-voltage transistor below the threshold voltage of the high-voltage transistor due to electron tunnelling. A high-voltage transistor may be particularly susceptible to GIDL because an overlap of a depletion region in a channel of the high-voltage transistor with the drain region of the high-voltage transistor can occur due to the high voltage applied to the drain region. Because GIDL occurs at sub-threshold voltages, GIDL can increase the off current (I_{off}) of a high-voltage transistor, which increases the power consumption of the high-voltage transistor.

Parasitic capacitance can occur in various regions of a high-voltage transistor, such as between a gate structure of the high-voltage transistor and a source/drain contact of the high-voltage transistor, between the gate structure and a channel region of the high-voltage transistor through a gate dielectric layer of the high-voltage transistor, and/or due to overlap of the gate structure and a drain region of the high-voltage transistor, among other examples. Parasitic capacitance reduces the switching speed of the high-voltage transistor in that the parasitic capacitance increases the resistance-capacitance delay (RC delay) of the high-voltage transistor.

In some implementations described herein, a high-voltage transistor includes an asymmetric gate dielectric layer and a gate structure that includes one or more asymmetric work function metal layers. The gate dielectric layer and the work function metal layer(s) are asymmetric in that the height of the gate dielectric layer and the height of the work function metal layer(s) on opposing sides of the gate structure are different. In particular, the height of the gate dielectric layer and the height of the work function metal layer(s) on a side of the gate structure facing the drain region of the high-voltage transistor are lower than the height of the gate dielectric layer and the height of the work function metal layer(s) on an opposing side of the gate structure facing the source region of the high-voltage transistor. The lower heights of the gate dielectric layer and the work function metal layer(s) on the drain side of the gate structure reduces (or prevents) an overlap of a depletion region and the drain region, which reduces the amount of electron tunneling (and therefore, the amount of GIDL in the high-voltage transistor) as well as the amount of gate-to-drain overlap parasitic capacitance (Cₒᵥ) in the high-voltage transistor. Thus, the lower heights of the gate dielectric layer and the work function metal layer(s) on the drain side of the gate structure enables a low off-current leakage to be achieved for the high-voltage transistor, and enables faster switching speeds to be achieved for the high-voltage transistor (e.g., due to lower RC delay).

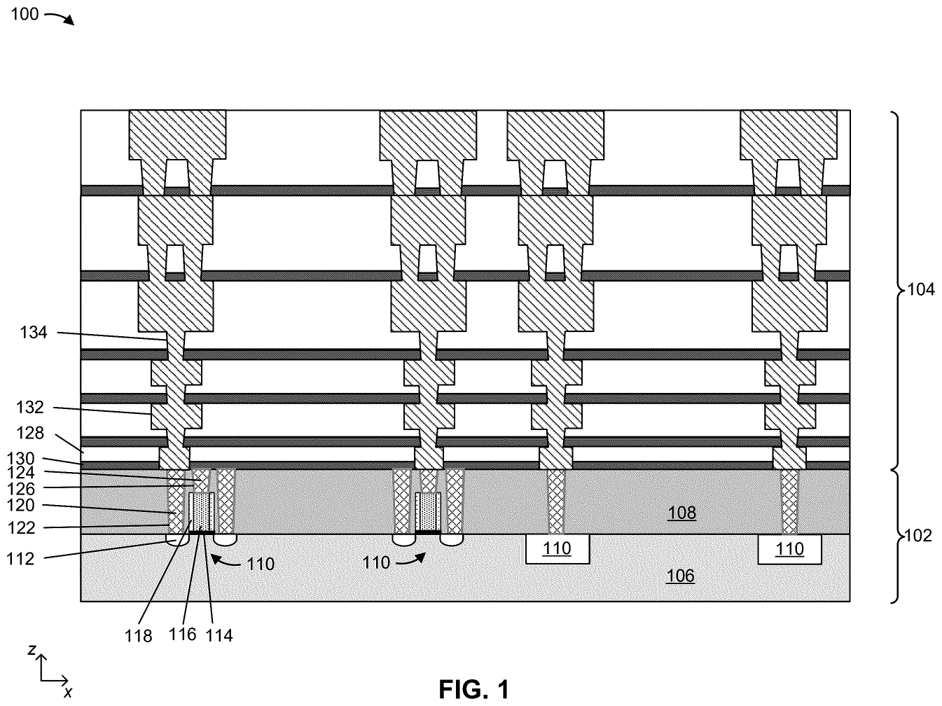

FIG. 1 is a diagram of a portion of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1, the semiconductor device 100 may include a device layer 102 and an interconnect layer 104 above the device layer 102 in a z-direction in the semiconductor device 100. The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

A dielectric layer 108 is included over the substrate layer 106. The dielectric layer 108 includes an interlayer dielectric (ILD) layer (e.g., an ILD0 layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 110 in the device layer 102. The dielectric layer 108 includes a silicon nitride (SiₓN_{y}), an oxide (e.g., a silicon oxide (SiOₓ) and/or another oxide material), and/or another type of dielectric material. The dielectric layer 108 may extend in the x-direction and/or in a y-direction in the semiconductor device 100.

The integrated circuit devices 110 may be included in and/or on the substrate layer 106, and/or in in the dielectric layer 108 in the device layer 102 of the semiconductor device 100. The integrated circuit devices 110 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

An integrated circuit device 110 may include a plurality of source/drain regions 112 that are grown and/or otherwise formed on and/or around portions of the substrate layer 106. “Source/drain region(s)” may refer to a source or a drain, individually or collectively, dependent upon the context. The source/drain regions 112 may be formed by epitaxially growing doped semiconductor regions and/or by another semiconductor process. In some implementations, the source/drain regions 112 are formed in recessed portions in the substrate layer 106. The recessed portions may be formed by strained source/drain (SSD) etching of the substrate layer 106 and/or another type etching operation.

An integrated circuit device 110 may further include a gate dielectric layer 114 between a gate structure 116 and the substrate layer 106. In some implementations, the gate dielectric layer 114 includes a low dielectric constant (low-k) dielectric material such as silicon oxide (SiOₓ). In some implementations, the gate dielectric layer 114 includes a high dielectric constant (high-k) dielectric material such as hafnium oxide (HfOₓ). The gate structure 116 may be located laterally between the source/drain regions 112. In some implementations, the gate structure 116 is formed of a polysilicon material. In these implementations, the polysilicon material may be doped with one or more types of dopants (e.g., p-type dopants, n-type dopants) to tune a work function of the gate structure 116. In some implementations, the gate structure 116 is formed of one or more metal materials (e.g., tungsten (W), titanium (Ti), cobalt (Co), and/or another metal. In these implementations, the gate structure 116 may include one or more types of metals (e.g., p-type metals, n-type metals) for tuning the work function of the gate structure 116.

Sidewall spacers 118 may be included on the sidewalls of the gate structure 116 to provide electrical isolation for the gate structure 116, among other examples. The sidewall spacers 118 may include a silicon oxide (SiOₓ), a silicon nitride (SiₓN_{y}), a silicon oxycarbide (SiOC), a silicon oxycarbonitride (SiOCN), and/or another suitable material.

The source/drain regions 112 are electrically coupled and/or physically coupled with source/drain contacts 120. The source/drain contacts 120 may include contact vias, contact plugs, and/or another type of contact structures that electrically connect the source/drain regions 112 of the integrated circuit devices 110 with the interconnect layer 104 of the semiconductor device 100. The source/drain contacts 120 include cobalt (Co), ruthenium (Ru), and/or another electrically conductive material or metal material. One or more liner layers 122 may be included on sidewalls of the source/drain contacts 120. The liner layer(s) 122 may include a barrier layer that is included to prevent or minimize diffusion of materials from the source/drain contacts 120 to the surrounding dielectric layers, an adhesion layer or glue layer that is included to promote adhesion between the source/drain contacts 120 and the surrounding dielectric layers, and/or another type of liner. Examples of materials for the liner layer(s) 122 include titanium nitride (TiN), tantalum nitride (TaN), and/or another suitable liner material.

The gate structures 116 maybe electrically coupled and/or physically coupled with gate contacts 124. The gate contacts 124 may include contact vias, contact plugs, and/or other types of contact structures that electrically connect the gate structures 116 of the integrated circuit devices 110 with the interconnect layer 104 of the semiconductor device 100. Alternatively, a gate structure 116 may be electrically coupled and/or physically coupled directly with the interconnect layer 104. The gate contacts 124 include cobalt (Co), ruthenium (Ru), and/or another electrically conductive material or metal material. One or more liner layers 126 may be included on sidewalls of the gate contacts 124. The liner layer(s) 126 may include a barrier layer that is included to prevent or minimize diffusion of materials from the gate contacts 124 to the surrounding dielectric layers, an adhesion layer or glue layer that is included to promote adhesion between the gate contacts 124 and the surrounding dielectric layers, and/or another type of liner. Examples of materials for the liner layer(s) 126 include titanium nitride (TiN), tantalum nitride (TaN), and/or another suitable liner material.

In some implementations, one or more of the integrated circuit devices 110 include a high-voltage transistor (or a medium voltage transistor). “High-voltage transistor” refers to a transistor that is configured to operate at higher operating voltages (e.g., higher gate voltages, higher source/drain voltages) than low voltage transistors. As an example, a high-voltage transistor may be configured to operate in a drain voltage range of approximately 9 volts to approximately 36 volts, whereas a low-voltage transistor may be configured to operate in a drain voltage range of approximately 0 volts to approximately 1.8 volts. However, other values for these ranges are within the scope of the present disclosure.

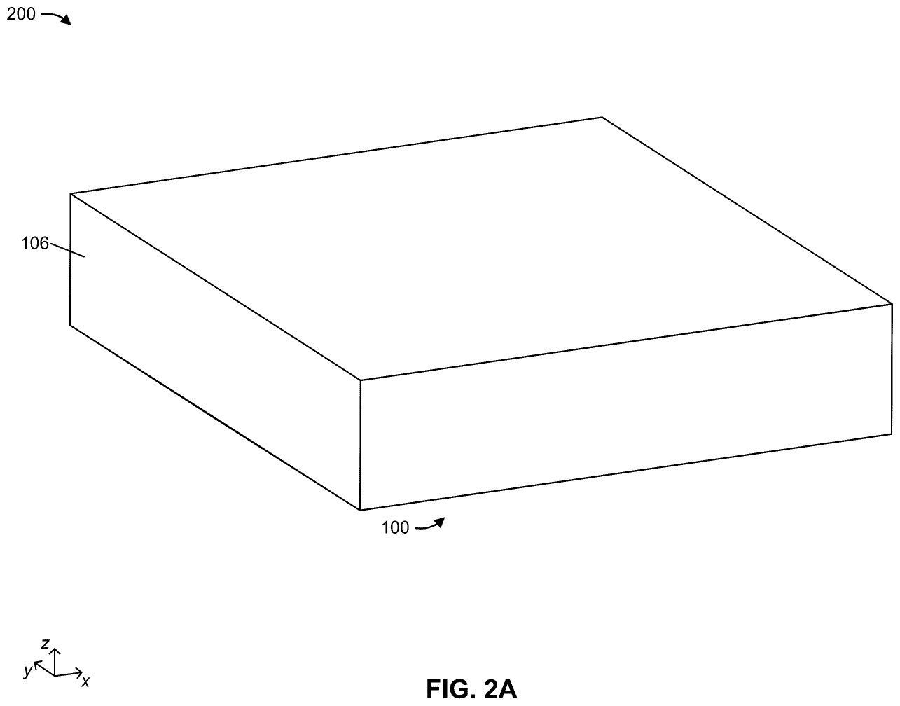

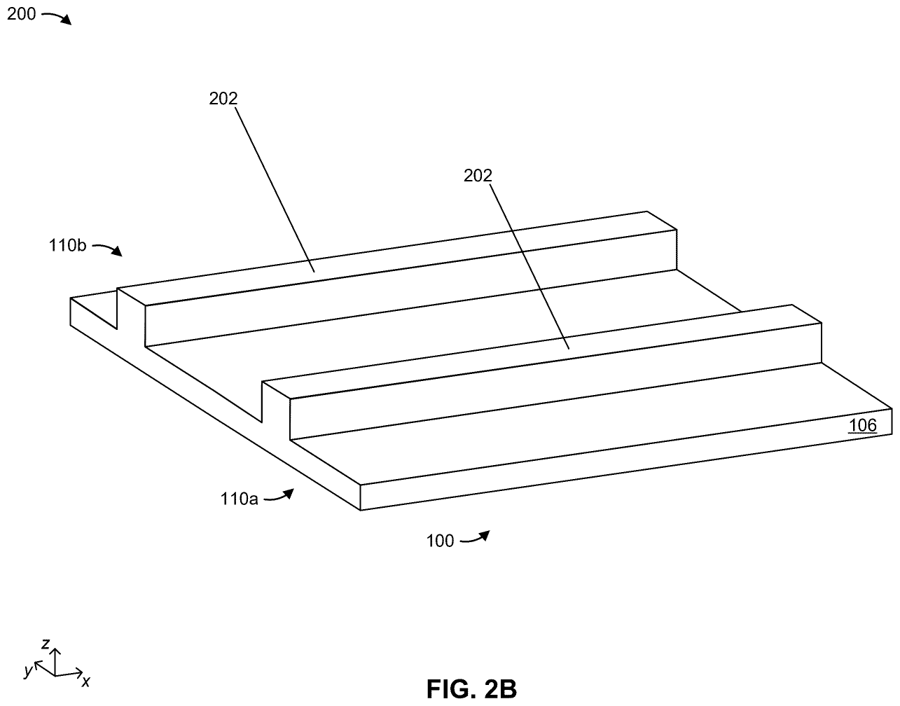

In some implementations, a high-voltage transistor may be implemented as a high-voltage planar transistor structure that includes one or more planar channels. In some implementations, a high-voltage transistor may be implemented as a high-voltage finFET structure that includes one or more fin-based channels. In some implementations, a high-voltage transistor may be implemented as a high-voltage GAA transistor structure that includes one or more nanostructure channels. FIGS. 2A-2B, 3A-3B, 4A-4D, 5A-5R, 6A-6F, and 7 illustrate examples of various manufacturing process operations for forming a high-voltage transistor (e.g., a high-voltage transistor that includes one or more fin-based channels).

The interconnect layer 104 of the semiconductor device 100 is included above the substrate layer 106 and above the integrated circuit devices 110 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include dielectric layers 128 and ESLs 130 that are arranged in an alternating manner in the z-direction. The dielectric layers 128 and the ESLs 130 may extend in the x-direction and/or in the y-direction in the semiconductor device 100.

The dielectric layers 128 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, a dielectric layer 128 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 130 may each include a silicon nitride (SiₓN_{y}), silicon carbide (SiC), silicon oxynitride (SiON), and/or another suitable dielectric material. In some implementations, a dielectric layer 128 and an ESL 130 include different dielectric materials to provide etch selectivity to enable various structures to be formed in the interconnect layer 104.

The interconnect layer 104 includes a plurality of conductive structures. The conductive structures are electrically coupled and/or physically coupled with one or more of the integrated circuit devices 110 in the device layer 102 and/or in the interconnect layer 104. The conductive structures enable signals and/or power to be provided to and/or from the integrated circuit devices 110.

The conductive structures include a combination of metallization structures 132 and interconnect structures 134. The metallization structures 132 may include trenches, conductive traces, and/or other types of conductive structures that primarily extend in the x-direction and/or in the y-direction in the interconnect layer 104. The interconnect structures 134 may include vias, plugs, conductive columns, and/or other types of conductive structures that primarily extend in the z-direction in the semiconductor device. In some implementations, a conductive structure in the interconnect layer 104 includes a dual damascene structure, which includes a combination of a metallization structure 132 and an interconnect structure 134.

The metallization structures 132 and the interconnect structures 134 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the metallization structures 132 and/or the interconnect structures 134 and the surrounding dielectric layers in the interconnect layer 104. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 132 and the interconnect structures 134 of the interconnect layer 104 may be arranged in a vertical manner (e.g., in the z-direction). In other words, a plurality of stacked metallization structures 132 and interconnect structures 134 may extend between the device layer 102 and a top of the interconnect layer 104 to facilitate electrical signals and/or power to be routed between the device layer 102 and connection structures (not shown) of the semiconductor device 100. The plurality of stacked metallization structures 132 may be arranged in layers that may be referred to as M-layers. For example, a metal-0 (M0) layer may be located at the bottom of the interconnect layer 104 and may be directly coupled with the device layer 102 (e.g., with source/drain contacts 120 and/or gate contacts 124 of the integrated circuit devices 110 in the device layer 102). A via-1 (V1) layer that includes one or more interconnect structures 134 may be included above the M0 layer. A metal-1 layer (M1) layer may be located above the V1 layer in the interconnect layer 104, a via-2 (V2) layer may be included above the M1 layer, a metal-2 layer (M2) layer may be located above the V2 layer, and so on. Additionally, via layers may be included between vertically arranged M-layers.

As indicated above, FIG. 1 is provided as an example. Other examples may differ from what is described with regard to FIG. 1.

FIGS. 2A and 2B are diagrams of an example implementation 200 of forming fin structures for high-voltage transistors in the device layer 102 of the semiconductor device 100 described herein. As shown in FIG. 2A, one or more of the operations in the example implementation 200 may be performed in connection with the substrate layer 106 of the semiconductor device 100. The substrate layer 106 may be provided in the form of a semiconductor wafer or another type of substrate.

As shown in FIG. 2B, fin structures 202 are formed in the substrate layer 106 of the semiconductor device 100. In some implementations, fin structures 202 may be formed for each of an integrated circuit device 110a and an integrated circuit device 110b. The integrated circuit device 110a may include an n-type high-voltage transistor structure (e.g., a n-type metal-oxide-semiconductor (NMOS) high-voltage transistor), and the integrated circuit device 110b may include a p-type high-voltage transistor structure (e.g., a p-type metal-oxide-semiconductor (PMOS) high-voltage transistor). The NMOS high-voltage transistor and the PMOS high-voltage transistor may enable complementary metal oxide semiconductor (CMOS) circuits to be implemented in the semiconductor device 100.

In some implementations, a pattern in a photoresist layer is used to form the fin structures 202. In these implementations, a deposition tool may be used to form the photoresist layer on the substrate layer 106 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch into the substrate layer 106 to form the fin structures 202. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). Additionally and/or alternatively, other patterning and etching techniques may be used to form the fin structure 202, such as multiple-patterning techniques including double patterning techniques (e.g., self-aligned double patterning (SADP) and/or quadruple patterning techniques (e.g., self-aligned quadruple patterning (SAQP), among other examples.

As further shown in FIG. 2B, the fin structures 202 may vertically extend above the substrate layer 106 in the z-direction in the semiconductor device 100. Moreover, the fin structures 202 may laterally extend along the substrate layer 106 in the x-direction in the semiconductor device 100. The fin structures 202 may be arranged in the y-direction in the semiconductor device 100.

As indicated above, FIGS. 2A and 2B are provided as an example. Other examples may differ from what is described with regard to FIGS. 2A and 2B.

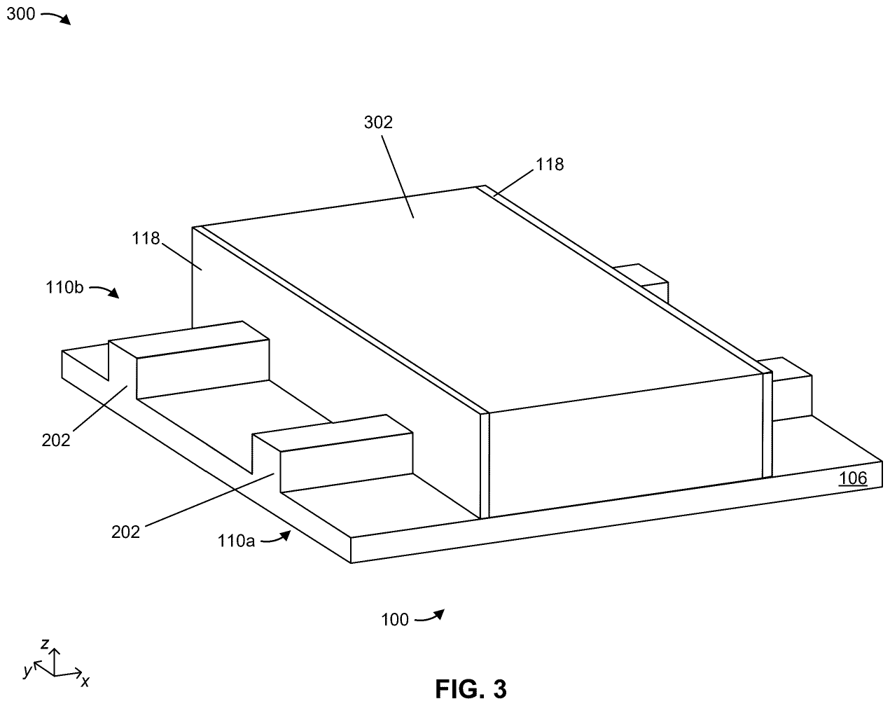

FIG. 3 is a diagram of an example implementation 300 of forming dummy gate structures for high-voltage transistors in the device layer 102 of the semiconductor device 100 described herein. In some implementations, one or more of the semiconductor processing operations described in connection with FIG. 3 may be performed after one or more of the semiconductor processing operations described in connection with FIGS. 2A and/or 2B.

As shown in FIG. 3, one or more dummy gate structures 302 may be formed over the fin structures 202 of the integrated circuit device 110a (e.g., the NMOS high-voltage transistor) and the integrated circuit device 110b (e.g., the PMOS high-voltage transistor). In some implementations, separate dummy gate structures 302 are formed for the integrated circuit device 110a and the integrated circuit device 110b. In some implementations, the same dummy gate structure 302 spans across the fin structures 202 of the integrated circuit device 110a and the integrated circuit device 110b.

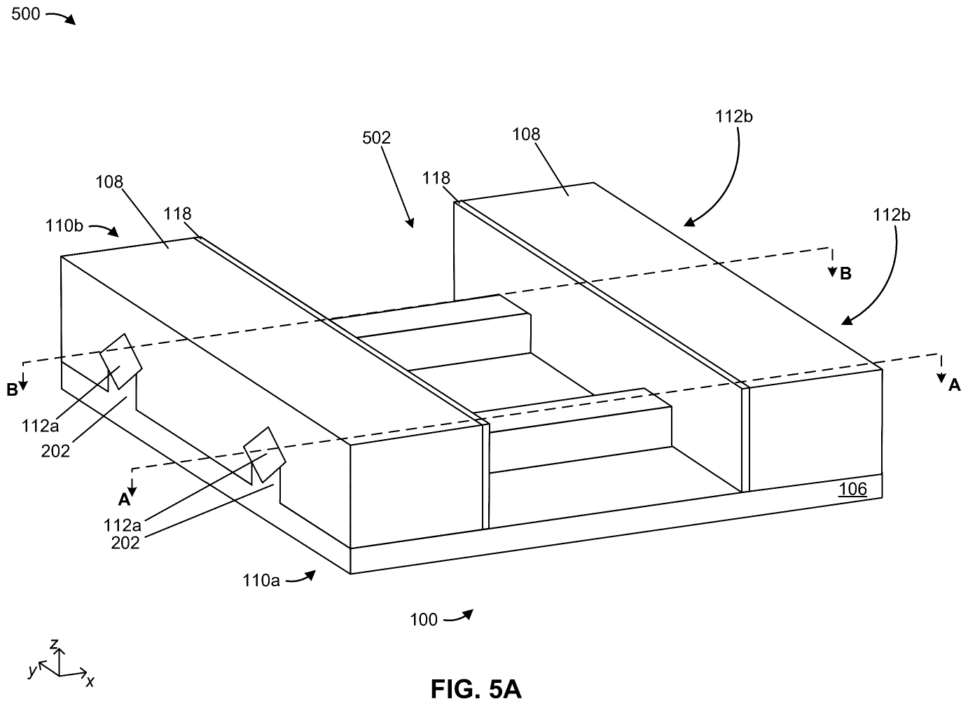

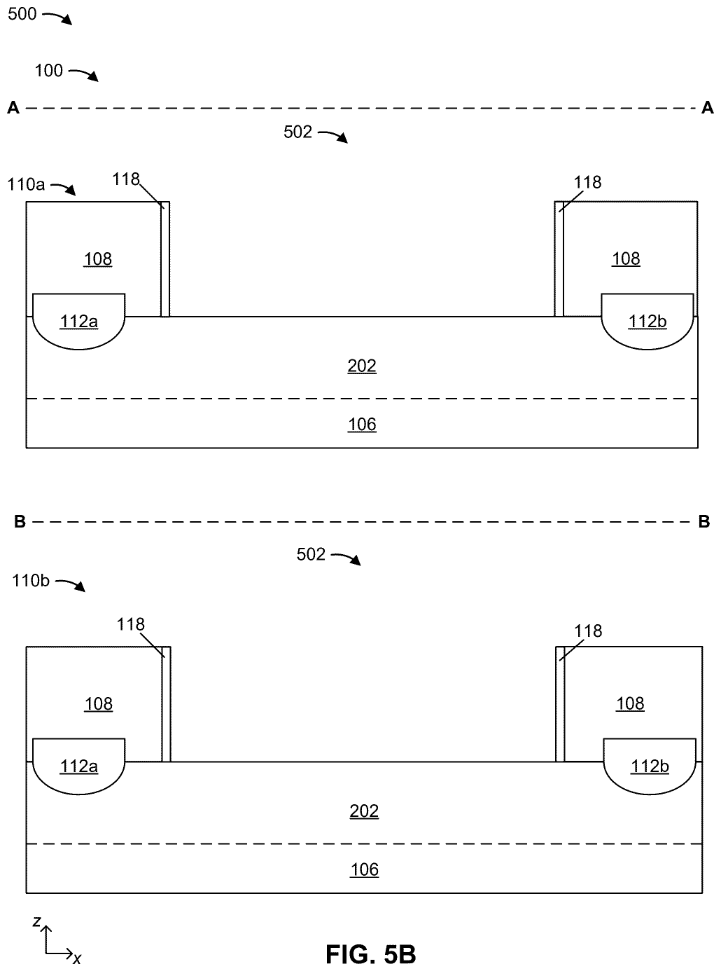

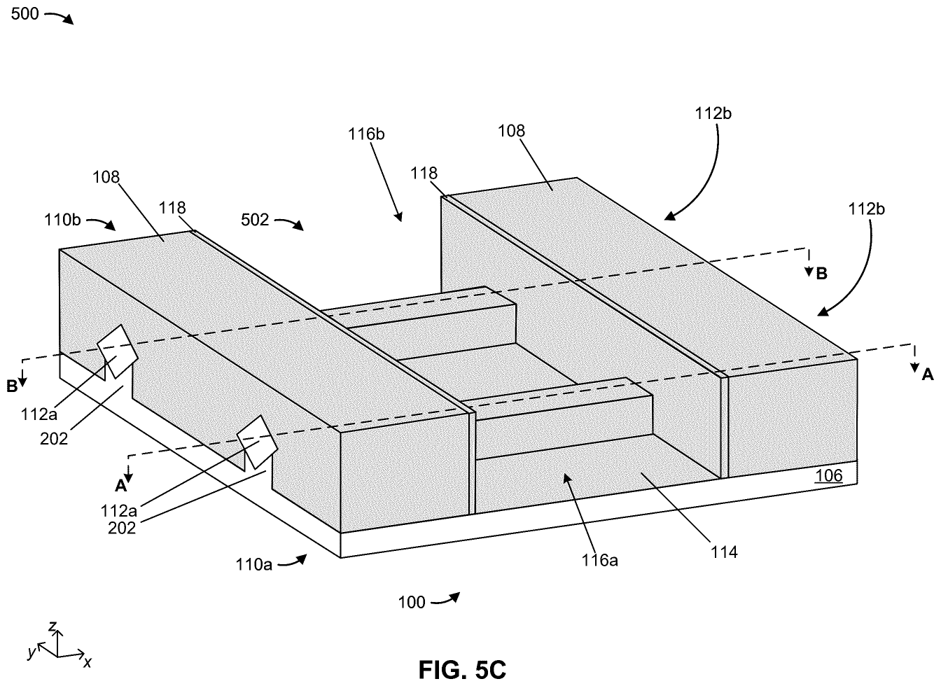

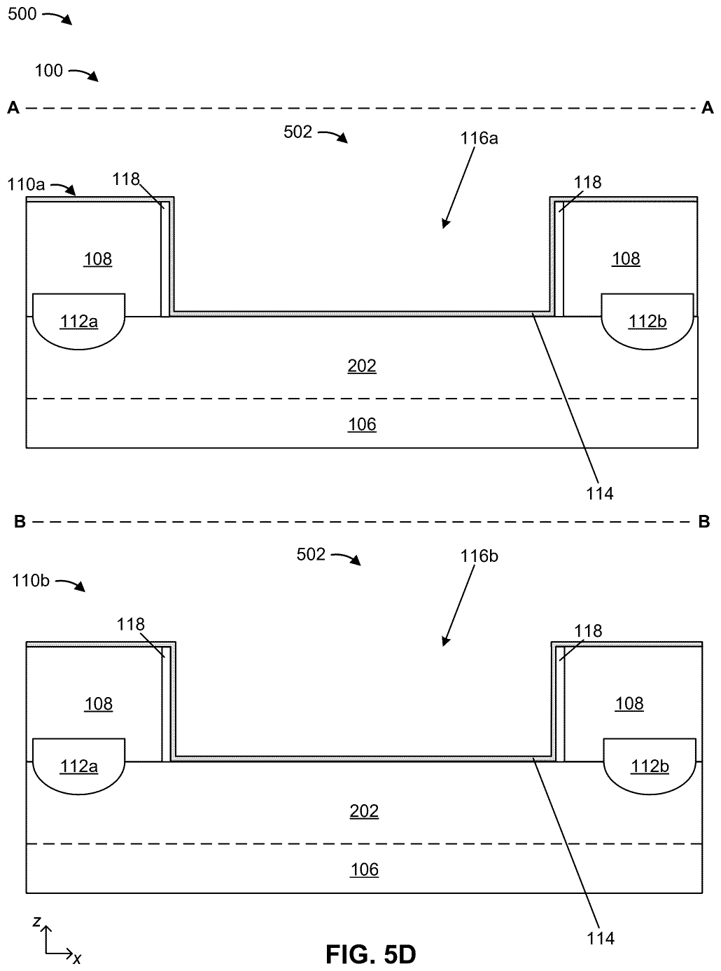

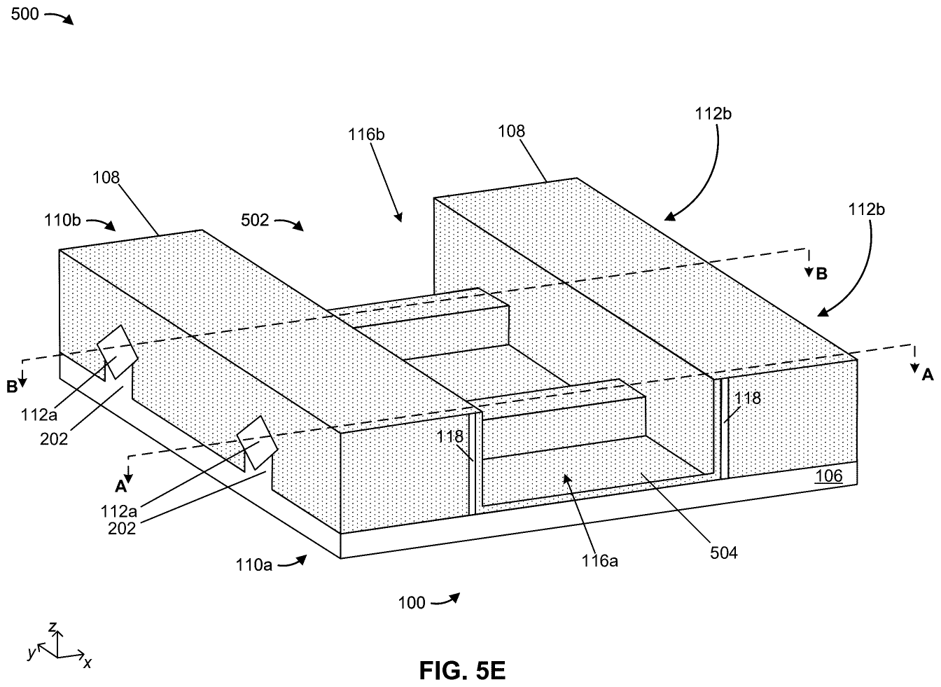

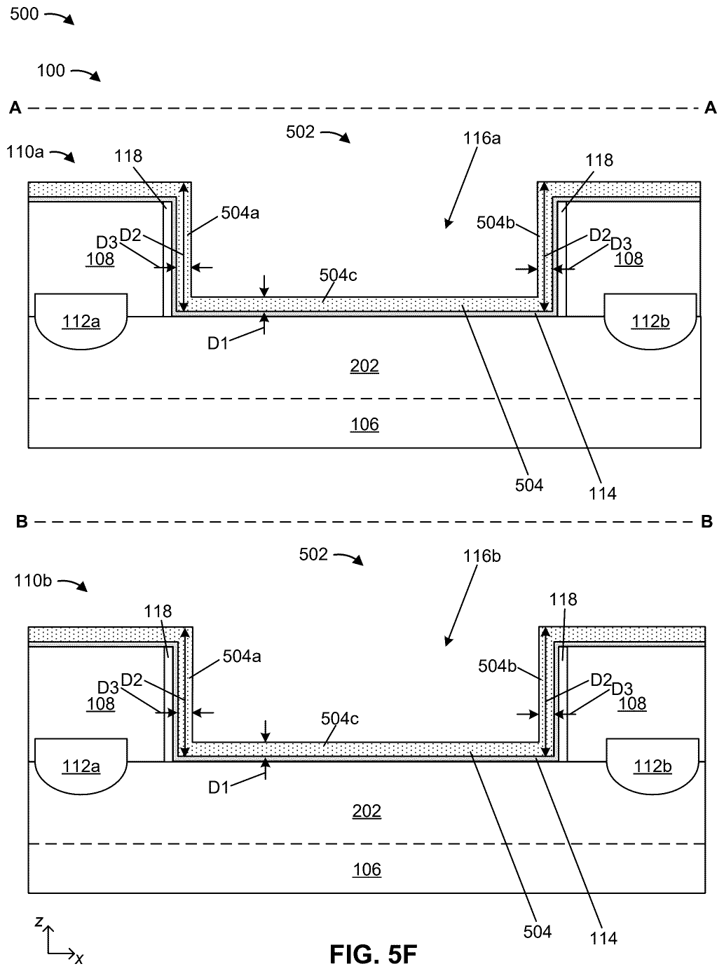

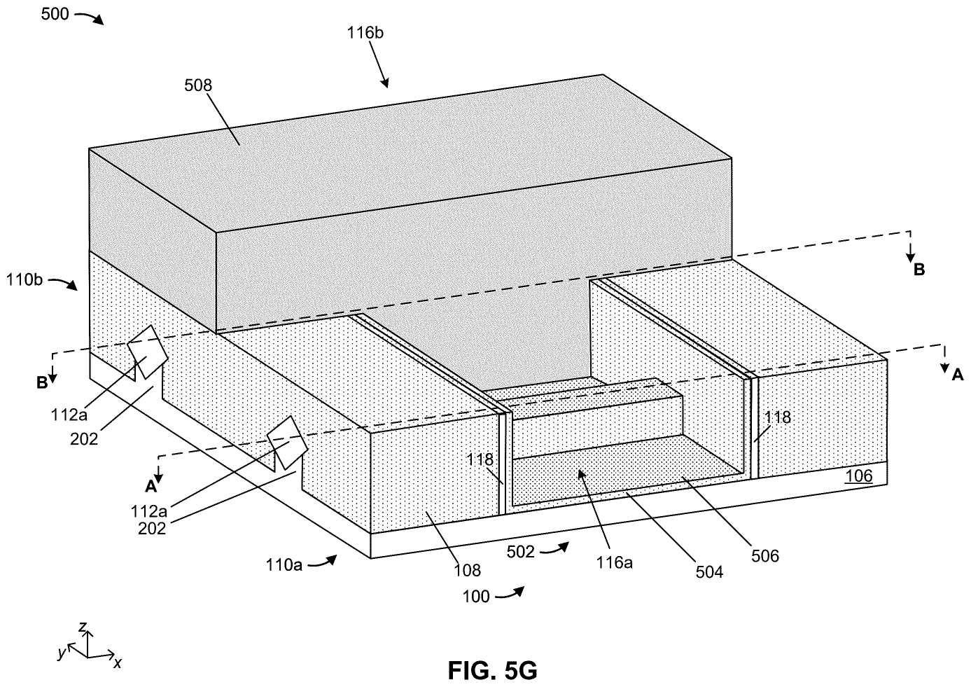

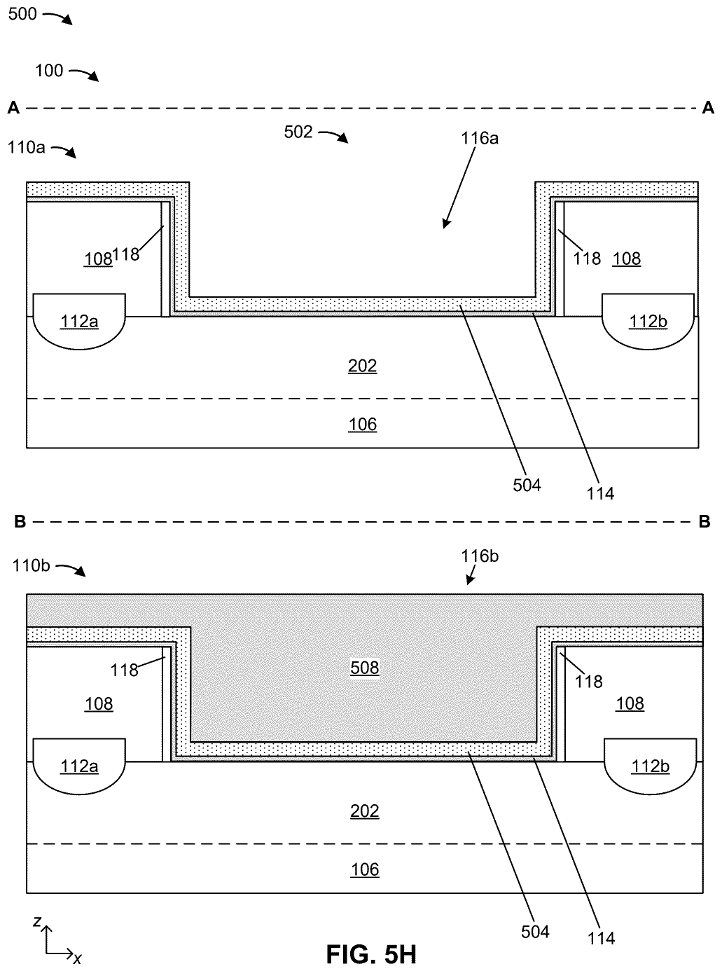

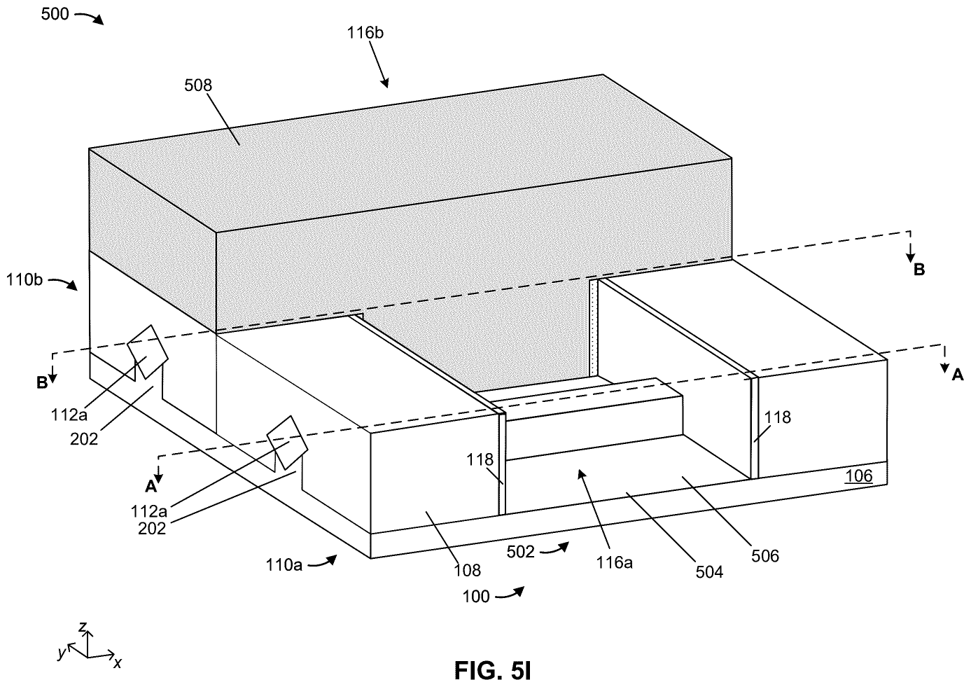

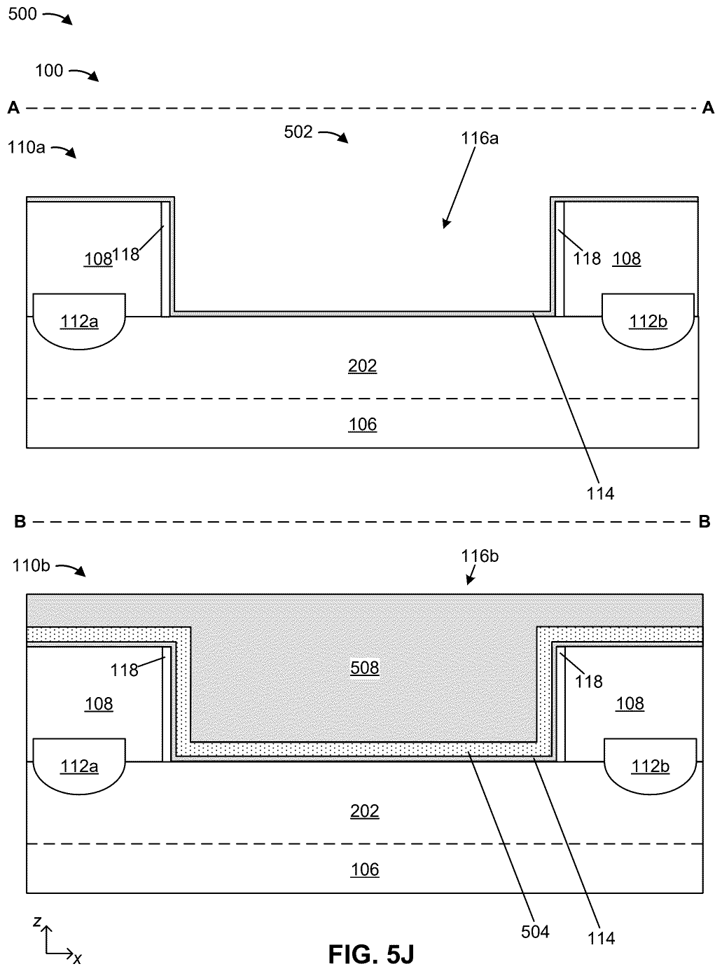

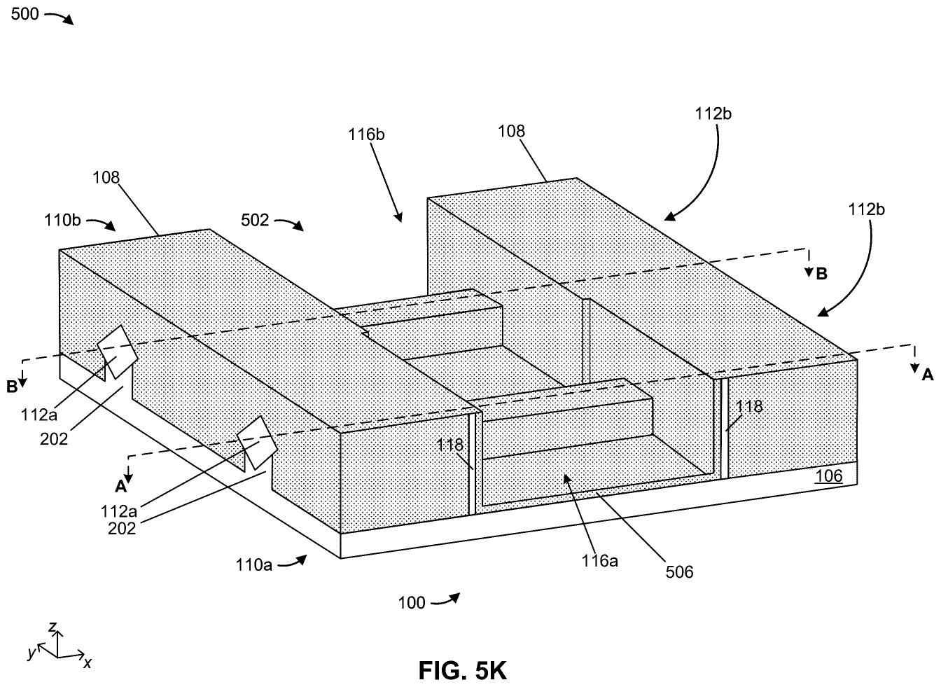

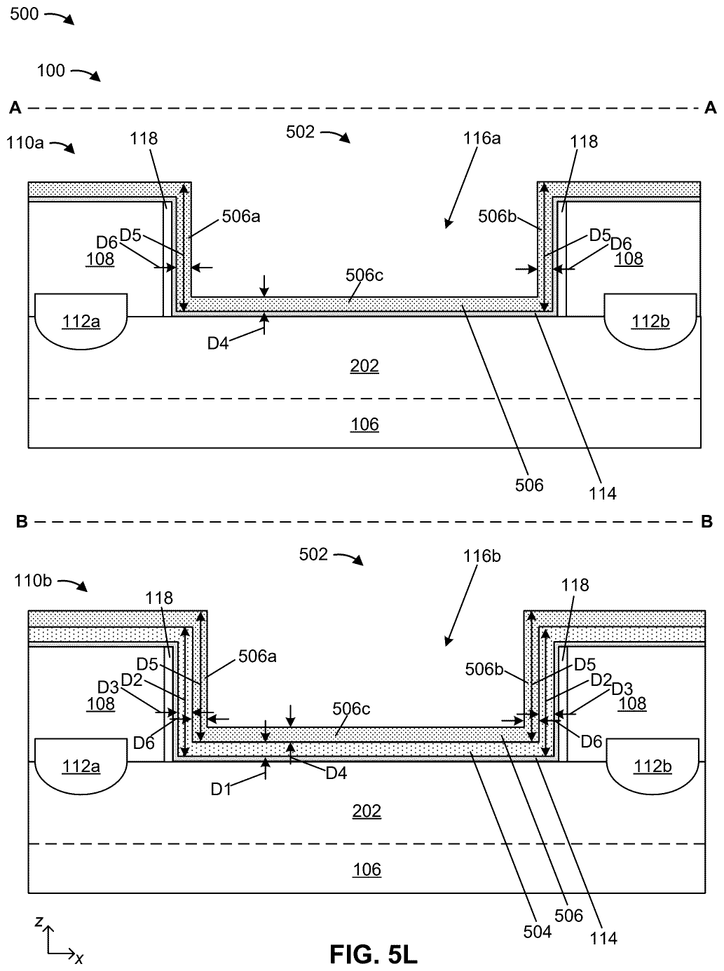

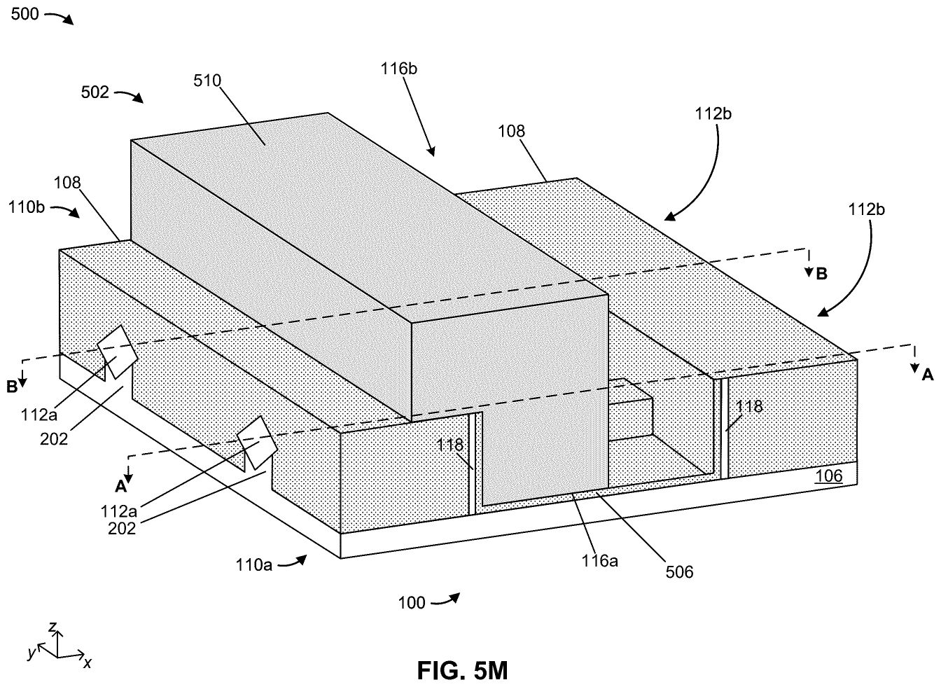

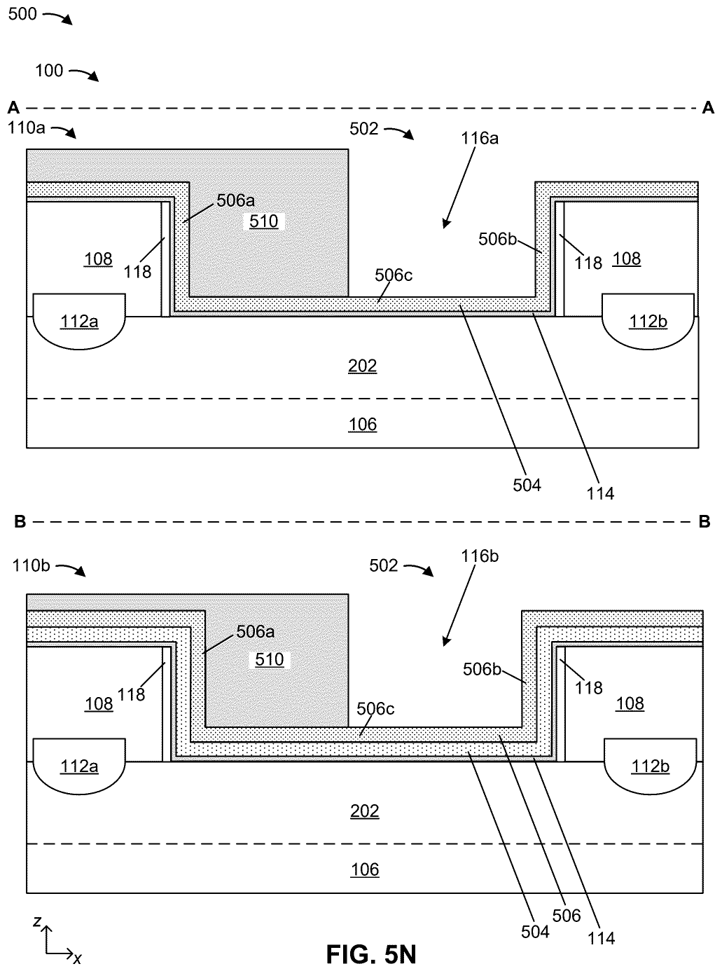

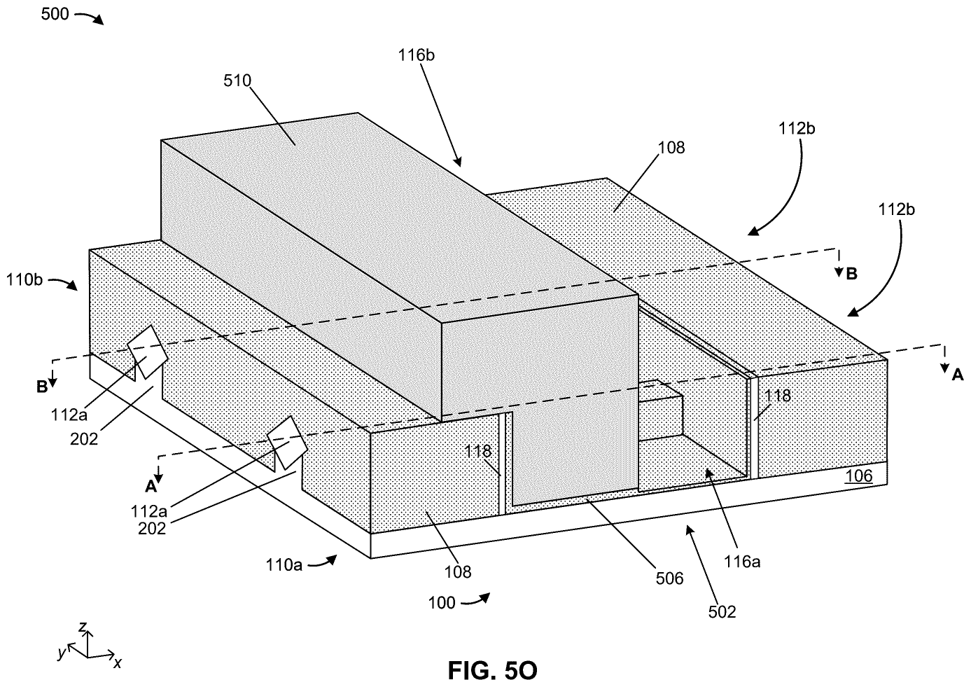

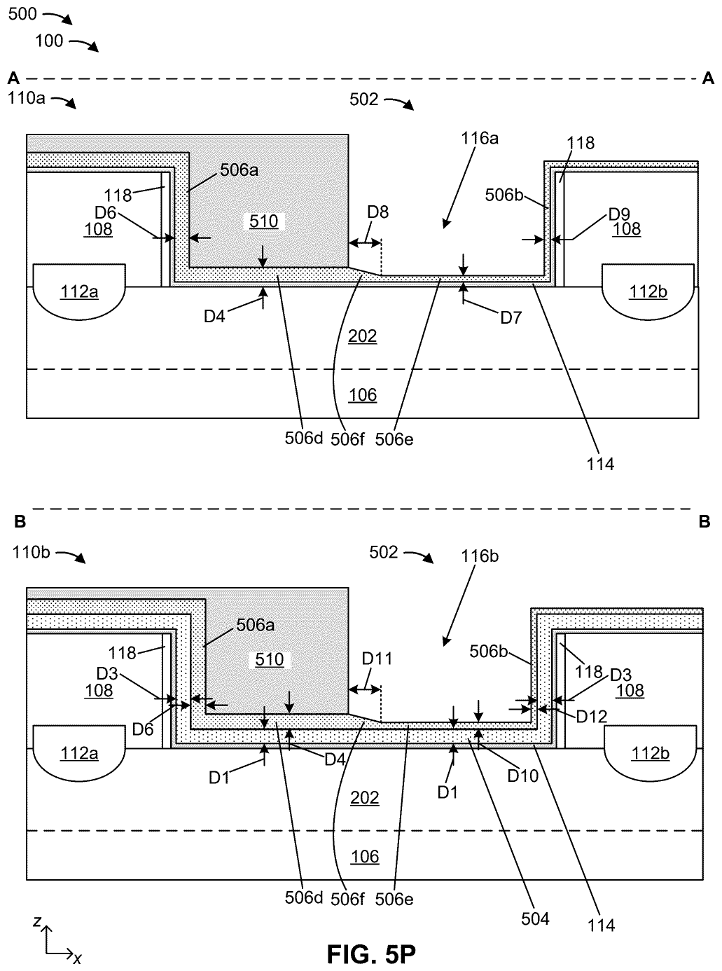

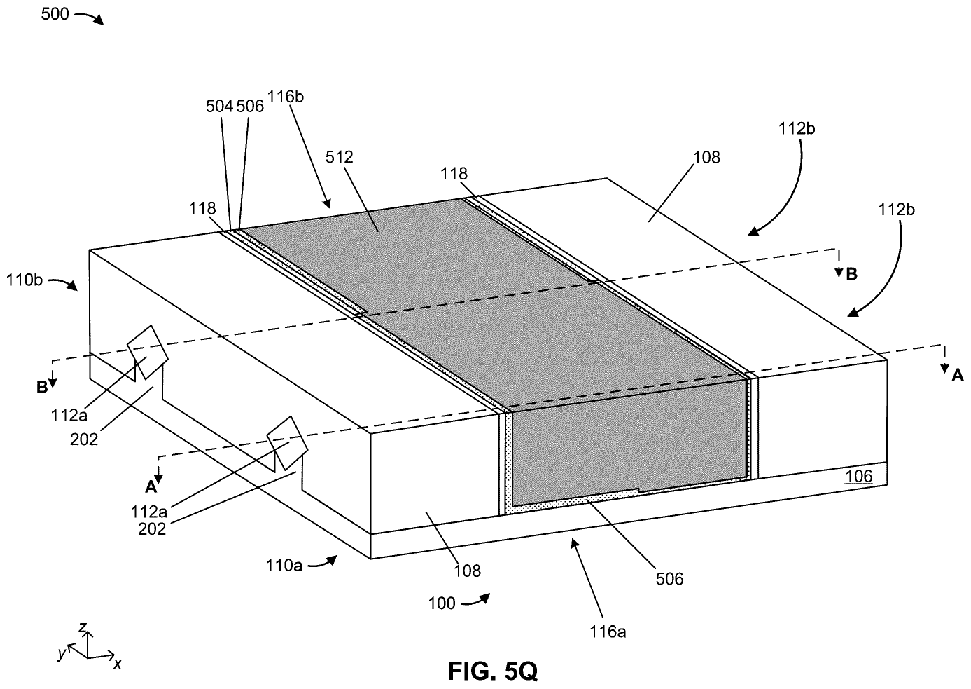

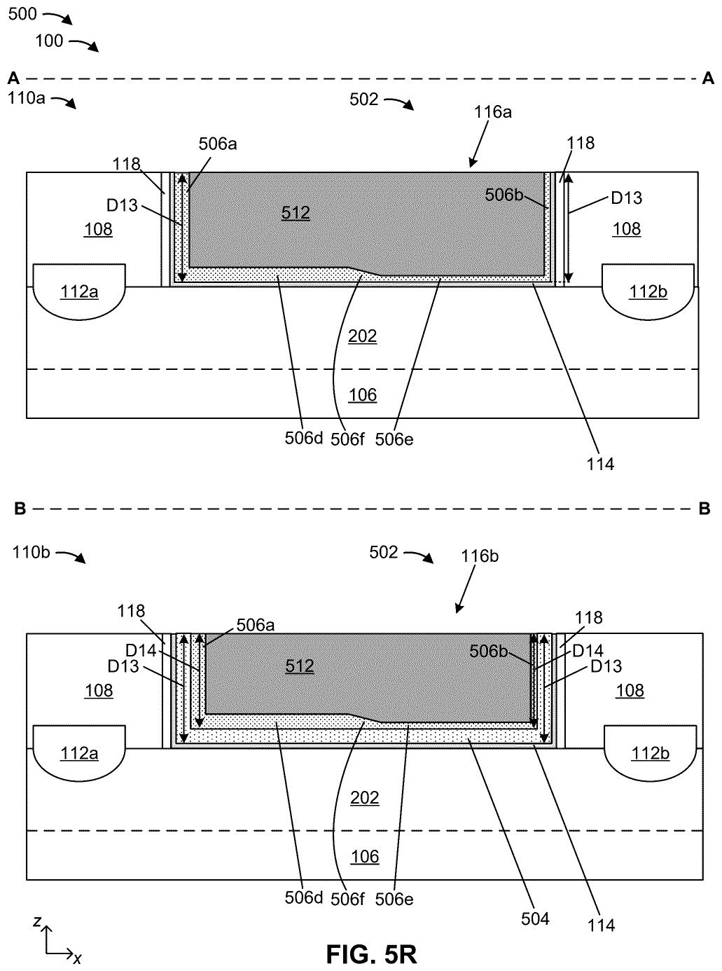

The term “dummy,” as used herein, refers to a sacrificial structure that is removed in a later stage of the process for forming the integrated circuit devices 110a and 110b, and will be replaced with another structure such as a metal gate structure (e.g., a gate structure 116). The dummy gate structures 302 may include polysilicon structures and/or structures that include another suitable material that can be selectively removed in subsequent processing operations. The process for replacing the dummy gate structures 302 is referred to as a replacement gate process. “Replacement gate process” refers to manufacturing a gate structure 116 at a later stage of the overall gate manufacturing process. An example replacement gate process is illustrated and described in connection with FIGS. 5A-5R.

A deposition tool may be used to deposit the dummy gate structures 302 using a physical vapor deposition (PVD) technique, a chemical vapor deposition (CVD) technique (e.g., low-pressure CVD (LPCVD) and/or plasma-enhanced CVD (PECVD), among other examples), an atomic layer deposition (ALD) technique, and/or another suitable deposition technique. In some implementations, a layer of polysilicon material is deposited, patterned, and etched to define the dummy gate structures 302. In some implementations, a planarization tool is used to perform a planarization operation (e.g., a chemical-mechanical planarization (CMP) operation) to planarize the dummy gate structures 302 after the dummy gate structures 302 are deposited.

As further shown in FIG. 3, the dummy gate structures 302 may wrap around the fin structures 202 of the integrated circuit devices 110a and 110b on at least three sides of the fin structures 202. In some implementations, portions of the dummy gate structures 302 are deposited onto the substrate layer 106. Alternatively, shallow trench isolation (STI) regions may be formed on portions of the substrate layer 106 adjacent to the fin structures 202 such that the dummy gate structures 302 are deposited onto the STI regions instead of on the substrate layer 106. The STI regions provide electrical isolation for gate structures 116 that are formed in place of the dummy gate structures 302, which reduces gate leakage through the substrate layer 106.

In some implementations, sidewall spacers 118 are formed on sidewalls of the dummy gate structures 302. The sidewall spacers 118 may be retained in the replacement gate process such that the sidewall spacers 118 are included between the gate structures 116 and source/drain regions of the integrated circuit devices 110a and/or 110b.

As indicated above, FIG. 3 is provided as an example. Other examples may differ from what is described with regard to FIG. 3.

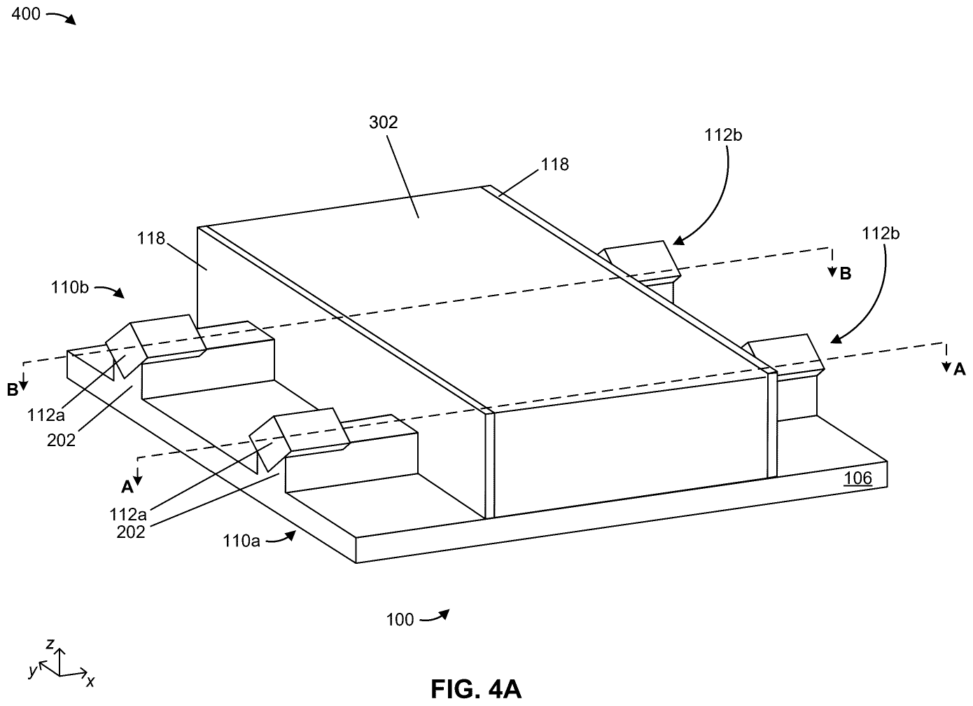

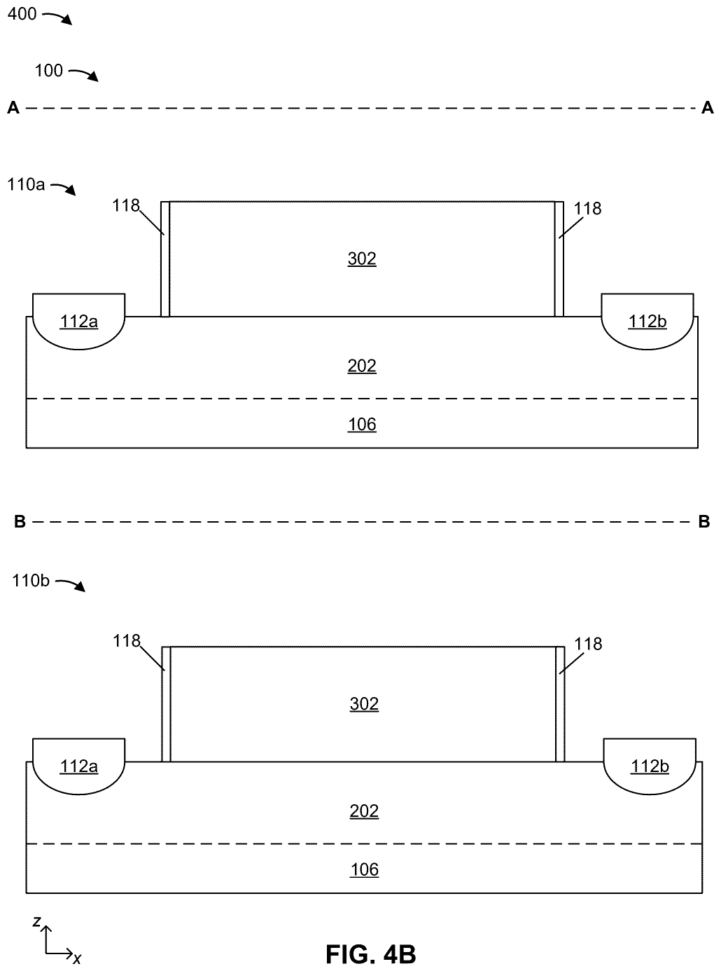

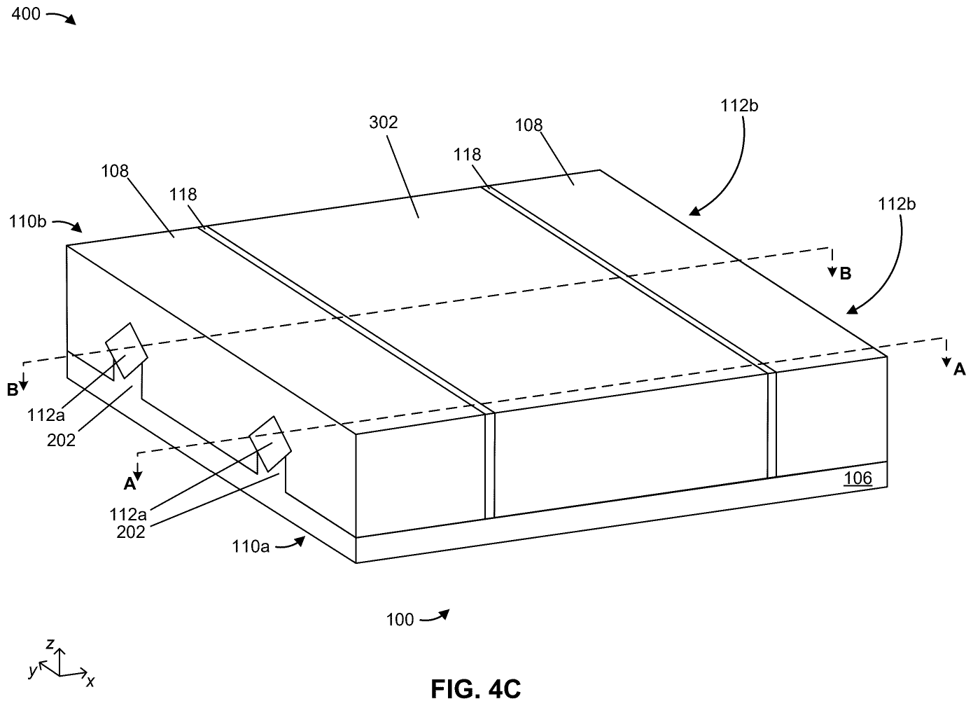

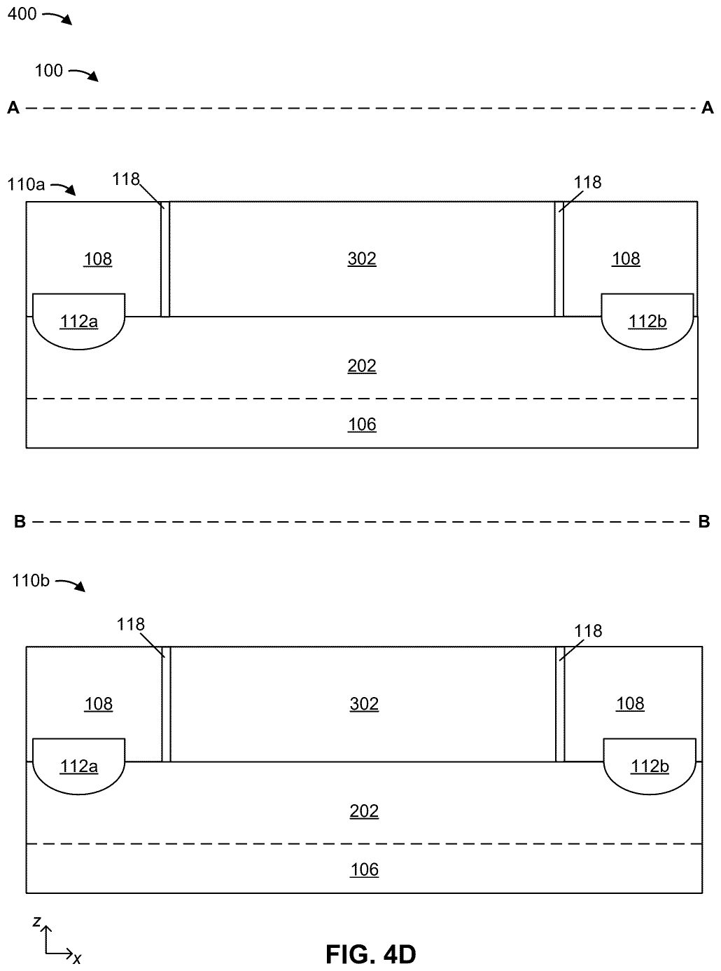

FIGS. 4A-4D are diagrams of an example implementation 400 of forming source/drain regions for high-voltage transistors in the device layer 102 of the semiconductor device 100 described herein. In some implementations, one or more of the semiconductor processing operations described in connection with FIGS. 4A-4D may be performed after one or more of the semiconductor processing operations described in connection with FIGS. 2A, 2B, and/or 3.

As shown in FIG. 4A, source/drain regions 112a and 112b may be formed on the fin structure 202 of the integrated circuit device 110a (e.g., the NMOS high-voltage transistor) such that the source/drain regions 112a and 112b are located laterally adjacent to opposing sides of the dummy gate structure 302 in the x-direction. Similarly, source/drain regions 112a and 112b may be formed on the fin structure 202 of the integrated circuit device 110b (e.g., the PMOS high-voltage transistor) such that the source/drain regions 112a and 112b are located laterally adjacent to opposing sides of the dummy gate structure 302 in the x-direction.

In some implementations, the source/drain regions 112a may be referred to as source regions of the integrated circuit devices 110a and 110b, and the source/drain regions 112b may be referred to as drain regions of the integrated circuit devices 110a and 110b. In some implementations, the source/drain regions 112b may be configured to operate at high voltages of up to approximately 36 volts or greater.

The source/drain regions 112a and 112b may be formed in recesses in the fin structures 202. The fin structures 202 may be etched (e.g., using an etch tool) to form the recesses, and the etch operation to form the recesses may be referred to as a strained source/drain (SSD) etch operation. In some implementations, the etch operation includes a plasma etch technique, a wet chemical etch technique, and/or another type of etch technique.

A deposition tool may be used to form the source/drain regions 112a and 112b in the recesses using an epitaxial growth technique, in which layers of the epitaxial material of the source/drain regions 112a and 112b are grown in the recesses such that the layers of n-type source/drain material (e.g., for the integrated circuit device 110a) and/or layers of p-type source/drain material (e.g., for the integrated circuit device 110b) are formed by epitaxial growth in a particular crystalline orientation. The material (e.g., silicon (Si), germanium (Ge), gallium (Ga), or another type of semiconductor material) that is used to form the source/drain regions 112a and 112b of the integrated circuit device 110a may be doped with an n-type dopant (e.g., a type of dopant that includes electron donor atoms that create mobile electrons in the material), and the material (e.g., silicon (Si), germanium (Ge), gallium (Ga), or another type of semiconductor material) that is used to form the source/drain regions 112a and 112b of the integrated circuit device 110b may be doped with an p-type dopant (e.g., a type of dopant that includes electron acceptor atoms that create holes in the material). The material of the source/drain regions 112 and 112b may be doped by adding impurities (e.g., the p-type dopant, the n-type dopant) using a source gas that is used during the epitaxial operation. Examples of p-type dopants that may be used in the epitaxial operation include boron (B) or gallium (Ga), among other examples. Examples of n-type dopants that may be used in the epitaxial operation include phosphorous (P) or arsenic (As), among other examples.

FIG. 4B illustrates cross-section views along the line A-A in FIG. 4A (e.g., along the fin structure 202 of the integrated circuit device 110a in the x-direction) and along the line B-B in FIG. 4A (e.g., along the fin structure 202 of the integrated circuit device 110b in the x-direction). As shown in FIG. 4B, the source/drain regions 112a and 112b are located on opposing sides of the dummy gate structures 302 of the integrated circuit devices 110a and 110b. The source/drain regions 112a and 112b may be included on, and may extend into, the fin structures 202.

Moreover, the source/drain regions 112a and 112b may extend above the tops of the fin structures 202.

As shown in FIGS. 4C and 4D, the dielectric layer 108 may be formed over and/or on the source/drain regions 112a and 112b of the integrated circuit devices 110a and 110b. The dielectric layer 108 fills in the areas around the dummy gate structures 302 and over the source/drain regions 112a and 112b. The dielectric layer 108 may be formed to define the space that results from removal of the dummy gate structures 302. Thus, the dielectric layer 108 functions as a self-aligned mask for forming the gate structures 116 in the areas previous occupied by the dummy gate structures 302.

A deposition tool may be used to deposit the dielectric layer 108 using a PVD technique, a CVD technique, an ALD technique, an oxidation technique, and/or another suitable deposition technique. In some implementations, a planarization tool is used to perform a planarization operation (e.g., a CMP operation) to planarize the dielectric layer 108 after the dielectric layer 108 is deposited. In some implementations, the dielectric layer 108 is formed to a height (or thickness) such that the dielectric layer 108 covers the dummy gate structures 302. In these implementations, the CMP operation removes material from the dielectric layer 108 such that the top surface of the dielectric layer 108 is approximately co-planar with top surfaces of the dummy gate structures 302.

As indicated above, FIGS. 4A-4D are provided as an example. Other examples may differ from what is described with regard to FIGS. 4A-4D.

FIGS. 5A-5R are diagrams of an example implementation 500 of a replacement gate process for high-voltage transistors in the device layer 102 of the semiconductor device 100 described herein. In some implementations, one or more of the semiconductor processing operations described in connection with FIGS. 5A-5R may be performed after one or more of the semiconductor processing operations described in connection with FIGS. 2A, 2B, 3, and/or 4A-4D.

As shown in FIGS. 5A and 5B, the replacement gate process includes removing the dummy gate structures 302 from the integrated circuit device 110a (e.g., the NMOS high-voltage transistor) and the integrated circuit device 110b (e.g., the PMOS high-voltage transistor). In some implementations, an etch tool is used to perform one or more etch operations to remove the dummy gate structures 302. The one or more etch operations may include a wet etch operation, a dry etch operation (e.g., gas-based etch operation, a plasma-based etch operation), and/or another type of etch operation.

As further shown in FIGS. 5A and 5B, removal of the dummy gate structures 302 leaves behind recesses 502 in the dielectric layer 108 between the source/drain regions 112a and 112b of the integrated circuit devices 110a and 110b.

As shown in FIGS. 5C and 5D, a gate dielectric layer 114 is formed in the recesses 502 for an n-type gate structure 116a of the integrated circuit device 110a and for a p-type gate structure 116b of the integrated circuit device 110b. The gate dielectric layer 114 may be formed on the bottom surfaces of the recesses 502 and on the sidewalls of the recesses 502 facing the source/drain regions 112a and 112b. The gate dielectric layer 114 may also be formed on the tops and sidewalls of the fin structures 202 that are exposed in the recesses 502. In some implementations, the gate dielectric layer 114 is formed on the top surface of the dielectric layer 108.

A deposition tool may be used to deposit the gate dielectric layer 114 using a PVD technique, a CVD technique, an ALD technique, and/or another suitable deposition technique. The gate dielectric layer 114 may be deposited using a conformal deposition technique such that the gate dielectric layer 114 conforms to the surfaces and/or profiles of the recesses 502.

As shown in FIGS. 5E and 5F, a p-type work function metal layer 504 is formed in the recesses 502 for the n-type gate structure 116a and for the p-type gate structure 116b. The p-type work function metal layer 504 may also be formed along the top surface of the dielectric layer 108. A deposition tool may be used to deposit the p-type work function metal layer 504 using a PVD technique, a CVD technique, an ALD technique, and/or another suitable deposition technique.

The p-type work function metal layer 504 may be deposited on the gate dielectric layer 114 in the recesses 502 such that the p-type work function metal layer 504 is formed on the bottom surfaces of the recesses 502 and on the sidewalls of the recesses 502 facing the source/drain regions 112a and 112b. The p-type work function metal layer 504 may also be formed on the tops and sidewalls of the fin structures 202 that are exposed in the recesses 502.

The p-type work function metal layer 504 may include one or more p-type metals, such as tungsten (W), cobalt (Co), titanium nitride (TiN), tungsten nitride (WN), and/or another metal having a work function that is greater than approximately 4.7 electron volts (eV), among other examples. The p-type work function metal layer 504 may be included to tune the work function of the p-type gate structure 116b such that the work function is adjusted close to the valence band of the material of the substrate layer 106.

As shown in FIG. 5F, the p-type work function metal layer 504 may have one or more dimensions. For example, the p-type work function metal layer 504 may have sidewall segments that are included on sidewalls of the recesses 502, where a sidewall segment 504a is facing the source/drain region 112a of the integrated circuit device 110a and another sidewall segment 504b is facing the source/drain region 112b of the integrated circuit device 110a. Similarly, a sidewall segment 504a of the p-type work function metal layer 504 may be facing the source/drain region 112a of the integrated circuit device 110b and another sidewall segment 504b of the p-type work function metal layer 504 may be facing the source/drain region 112b of the integrated circuit device 110b. Bottom segments 504c of the p-type work function metal layer 504 may be included on the bottom surfaces of the recesses 502, including on the fin structures 202 exposed through the recesses 502.

The bottom segments 504c of the p-type work function metal layer 504 may have a vertical thickness (e.g., a z-direction thickness indicated in FIG. 5F as dimension D1) after formation of the p-type work function metal layer 504. The sidewall segments 504a and 504b may have a vertical height (e.g., a z-direction height indicated in FIG. 5F as dimension D2) and a lateral thickness (e.g., an x-direction thickness indicated in FIG. 5F as dimension D3) after formation of the p-type work function metal layer 504. The vertical height of the sidewall segments 504a and 504b may be greater than the height of the the sidewalls of the recesses 502. The lateral thicknesses of the sidewall segments 504a and 504b may be approximately equal on the sidewalls of the recesses 502. Moreover, the vertical thickness of the bottom segments 504c may be substantially uniform across the bottom surfaces of the recesses 502.

As shown in FIGS. 5G-5J, a portion of the p-type work function metal layer 504 may be removed from the n-type gate structure 116a of the integrated circuit device 110a. The p-type work function metal layer 504 may be removed from the n-type gate structure 116a so that the p-type work function metal layer 504 does not adversely affect the work function tuning of the n-type gate structure 116a.

As shown in FIGS. 5G and 5H, a masking layer 508 may be formed over the integrated circuit device 110b, including over the p-type gate structure 116b in the recess 502. In some implementations, the masking layer 508 is a hard mask layer (e.g., a silicon nitride (SiₓN_{y}) layer, a silicon oxynitride (SiON) layer) and is deposited using a deposition tool using a PVD technique, a CVD technique, and/or another suitable deposition technique. In some implementations, the masking layer 508 is a photoresist layer and is deposited using a deposition tool using a spin-coating technique. In some implementations, the masking layer 508 is also deposited over the integrated circuit device 110a and is subsequently removed from the integrated circuit device 110a (e.g., by etching and/or photolithography) such that the masking layer 508 remains on the integrated circuit device 110b.

As shown in FIGS. 5I and 5J, the p-type work function metal layer 504 may be etched based on the masking layer 508 such that the p-type work function metal layer 504 is removed from the n-type gate structure 116a. The masking layer 508 protects the p-type work function metal layer 504 on the p-type gate structure 116b such that the p-type work function metal layer 504 remains on the p-type gate structure 116b. An etch tool may be used to etch the p-type work function metal layer 504 using a wet etch technique, a dry etch technique (e.g., a gas-based etch, a plasma-based etch), and/or another suitable etch technique.

The remaining portions of the masking layer 508 may be removed from the semiconductor device 100 after removing the portion of the p-type work function metal layer 504 from the n-type gate structure 116a. In some implementations, a photoresist removal tool is used to remove the remaining portions of the masking layer 508 (e.g., using a chemical stripper, plasma ashing, etching, and/or another technique).

As shown in FIGS. 5K and 5L, an n-type work function metal layer 506 is formed in the recesses 502 for the n-type gate structure 116a and for the p-type gate structure 116b. For the p-type gate structure 116b, the n-type work function metal layer 506 may be deposited on the p-type work function metal layer 504. The n-type work function metal layer 506 may also be formed along the top surface of the dielectric layer 108. A deposition tool may be used to deposit the n-type work function metal layer 506 using a PVD technique, a CVD technique, an ALD technique, and/or another suitable deposition technique.

The n-type work function metal layer 506 may be deposited in the recesses 502 such that the n-type work function metal layer 506 is formed on the bottom surfaces of the recesses 502 and on the sidewalls of the recesses 502 facing the source/drain regions 112a and 112b. The n-type work function metal layer 506 may also be formed on the tops and sidewalls of the fin structures 202 that are exposed in the recesses 502.

The n-type work function metal layer 506 may include one or more metal materials that tune or adjust the work function of the n-type gate structure 116a near the conduction band of the material of the substrate layer 106 of the semiconductor device 100. In some implementations, the n-type work function metal layer 506 includes titanium aluminum (TiAl). In some implementations, the n-type work function metal layer 506 includes titanium aluminum carbon (TiAlC). In some implementations, the n-type work function metal layer 506 includes another aluminum-containing metal. In some implementations, another n-type metal material is included in the n-type work function metal layer 506.

As shown in FIG. 5L, the n-type work function metal layer 506 may have one or more dimensions. For example, the n-type work function metal layer 506 may have sidewall segments that are included on sidewalls of the recesses 502, where a sidewall segment 506a is facing the source/drain region 112a of the integrated circuit device 110a and another sidewall segment 506b is facing the source/drain region 112b of the integrated circuit device 110a. Similarly, a sidewall segment of the n-type work function metal layer 506 may be facing the source/drain region 112a of the integrated circuit device 110b and another sidewall segment of the n-type work function metal layer 506 may be facing the source/drain region 112b of the integrated circuit device 110b. Bottom segments of the n-type work function metal layer 506 may be included on the bottom surfaces of the recesses 502, including on the fin structures 202 exposed through the recesses 502.

The bottom segments of the n-type work function metal layer 506 may have a vertical thickness (e.g., a z-direction thickness indicated in FIG. 5L as dimension D4) after formation of the n-type work function metal layer 506. The sidewall segments may have a vertical height (e.g., a z-direction height indicated in FIG. 5L as dimension D5) and a lateral thickness (e.g., an x-direction thickness indicated in FIG. 5L as dimension D6) after formation of the n-type work function metal layer 506. The vertical heights of the sidewall segments may be greater than the height of the sidewalls of the recesses 502, and the lateral thicknesses of the sidewall segments may be approximately equal on the sidewalls of the recesses 502. Moreover, the vertical thicknesses of the bottom segments may be substantially uniform across the bottom surfaces of the recesses 502.

As shown in FIGS. 5M and 5N, a masking layer 510 may be formed over a portion of the integrated circuit device 110a and over a portion of the integrated circuit device 110b, and may extend into a portion of the recesses 502. For example, the masking layer 510 may be formed over a first portion of the n-type work function metal layer 506 of the integrated circuit device 110a, including a portion of the bottom segment of the n-type work function metal layer 506 and over the sidewall segment of the n-type work function metal layer 506 that is on the sidewall of the recess 502 facing the source/drain region 112a of the integrated circuit device 110a. As another example, the masking layer 510 may be formed over a first portion of the n-type work function metal layer 506 of the integrated circuit device 110b, including over a portion of the bottom segment of the n-type work function metal layer 506 and over the sidewall segment of the n-type work function metal layer 506 that is on the sidewall of the recess 502 facing the source/drain region 112a of the integrated circuit device 110b.

In some implementations, the masking layer 510 is a hard mask layer (e.g., a silicon nitride (SiₓN_{y}) layer, a silicon oxynitride (SiON) layer) and is deposited using a deposition tool using a PVD technique, a CVD technique, and/or another suitable deposition technique. In some implementations, the masking layer 508 is a photoresist layer and is deposited using a deposition tool using a spin-coating technique. In some implementations, the masking layer 510 fills in the entire area of the recesses 502 and is subsequently patterned by etching and/or photolithography.

As shown in FIGS. 5O and 5P, a second portion of the n-type work function metal layer 506 in the recess 502 between the source/drain regions 112a and 112b of the integrated circuit device 110a may be etched based on the masking layer 510. Similarly, a second portion of the n-type work function metal layer 506 in the recess 502 between the source/drain regions 112a and 112b of the integrated circuit device 110b may be etched based on the masking layer 510. This results in the second portion of the n-type work function metal layer 506 having a lesser thickness than the first portion of the n-type work function metal layer 506 that is covered by the masking layer 510.

The masking layer 510 may cover only a portion of the recesses 502 to enable an etchant to be provided into the recesses 502 to etch the second portions of the n-type work function metal layer 506. The etchant may include a wet etchant that omnidirectionally (e.g., isotropically) etches the second portions of the n-type work function metal layer 506. This enables the thicknesses of the second portions of the n-type work function metal layer 506 to be reduced in a substantially uniform manner. However, other etch techniques, including gas-based etch techniques and/or plasma-based etch techniques, are within the scope of the present disclosure.

As shown in FIG. 5P, a bottom segment 506d of the n-type work function metal layer 506 of the n-type gate structure 116a under the masking layer 510 remains at the initial vertical thickness (e.g., the dimension D4). However, another bottom segment 506e of the n-type work function metal layer 506 of the n-type gate structure 116a that is exposed through the masking layer 510 has a vertical (z-direction) thickness (indicated in FIG. 5P as dimension D7) that is less than the vertical thickness of the bottom segment 506d. A transition segment 506f of the n-type work function metal layer 506 of the n-type gate structure 116a is located between the bottom segments 506d and 506e. The transition segment 506f may have a non-uniform vertical (z-direction) thickness. In the transition segment 506f, the vertical (z-direction) thickness transitions between vertical thickness of the bottom segment 506d and the vertical thickness of the bottom segment 506e. In some implementations, the transition segment 506f has a sloped top surface such that the vertical thickness of the transition segment 506f gradually and substantially uniformly decreases from the bottom segment 506d to the bottom segment 506e. Alternatively, the transition segment 506f may have a stepped top surface or another top surface profile.

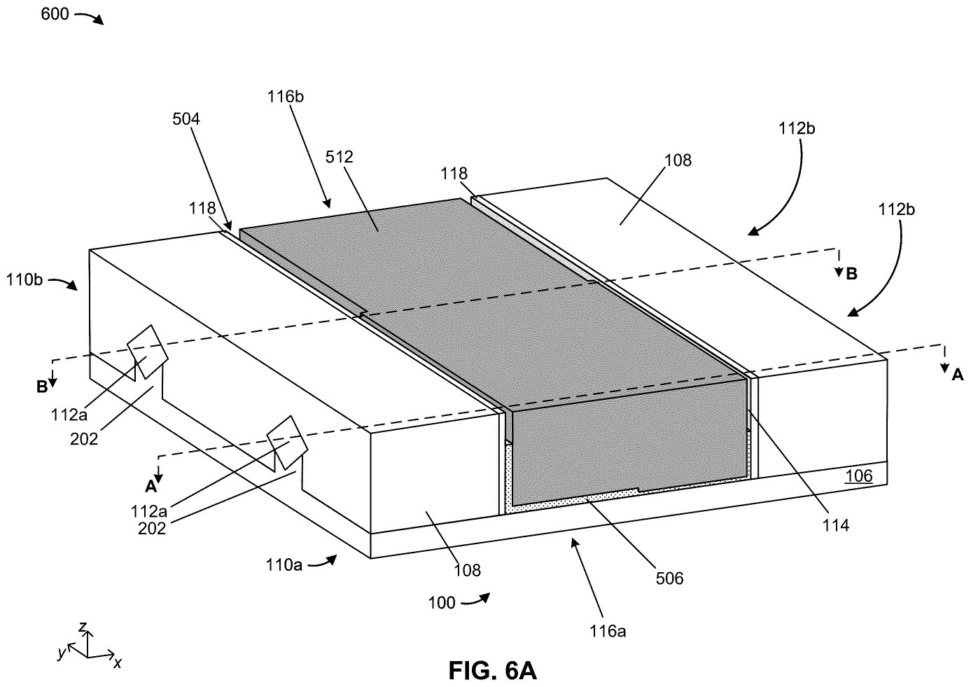

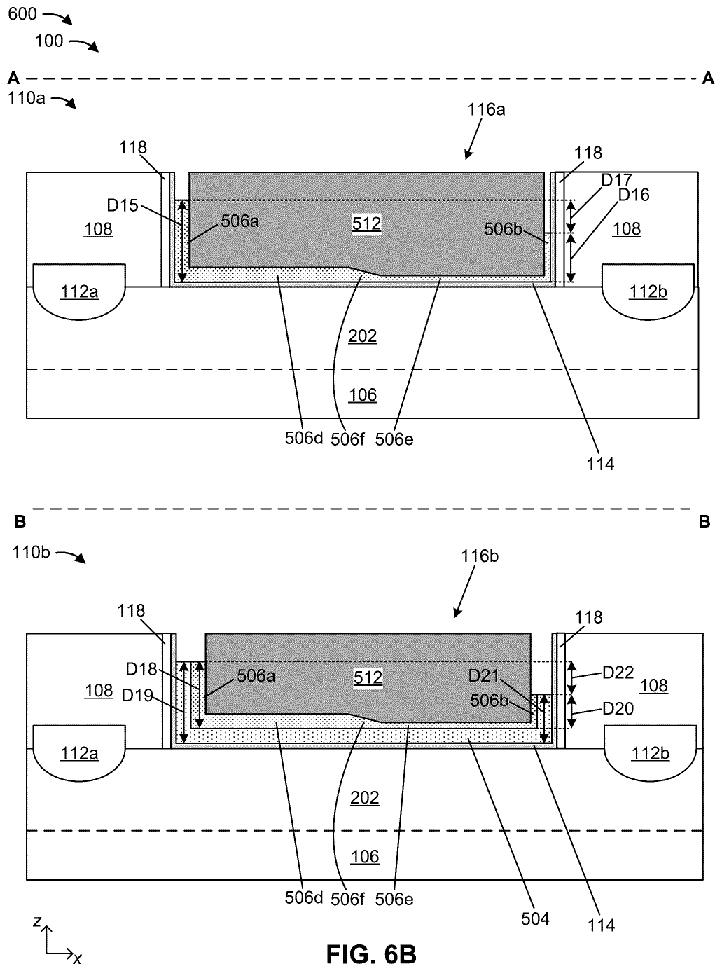

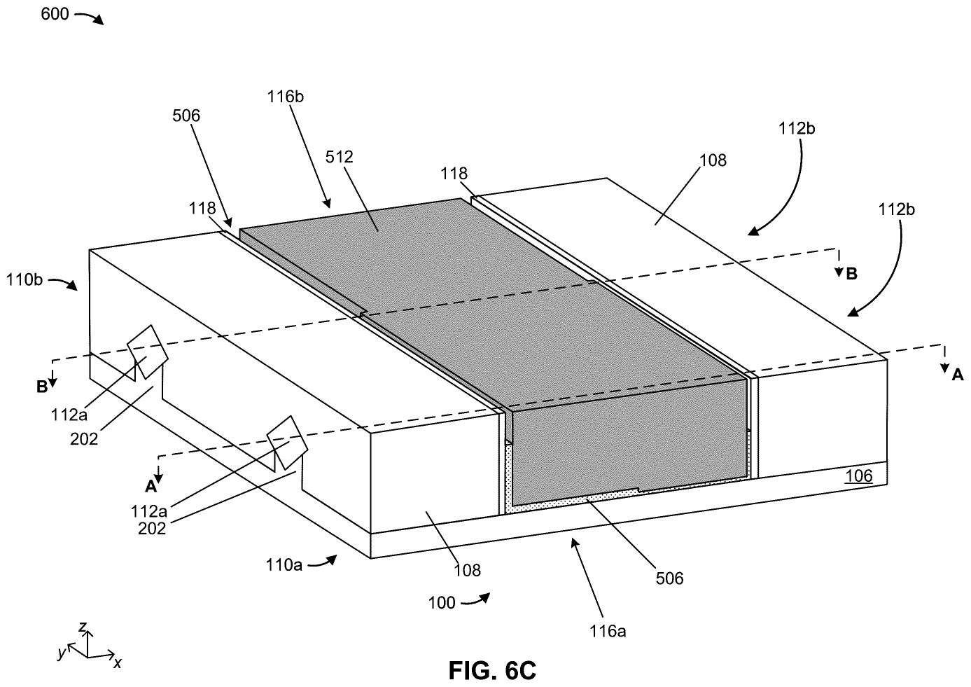

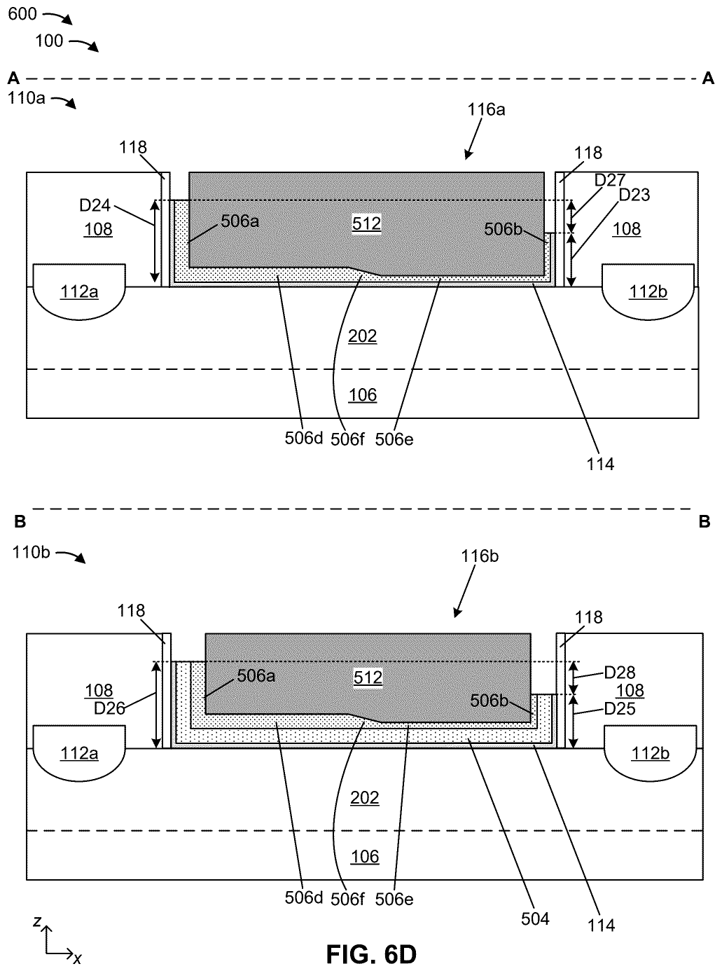

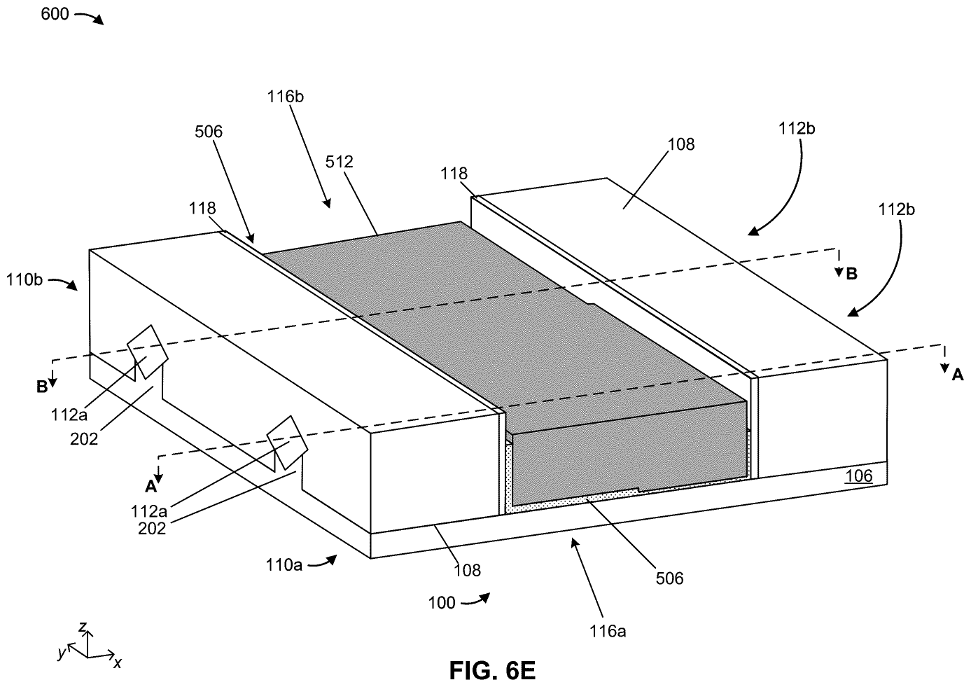

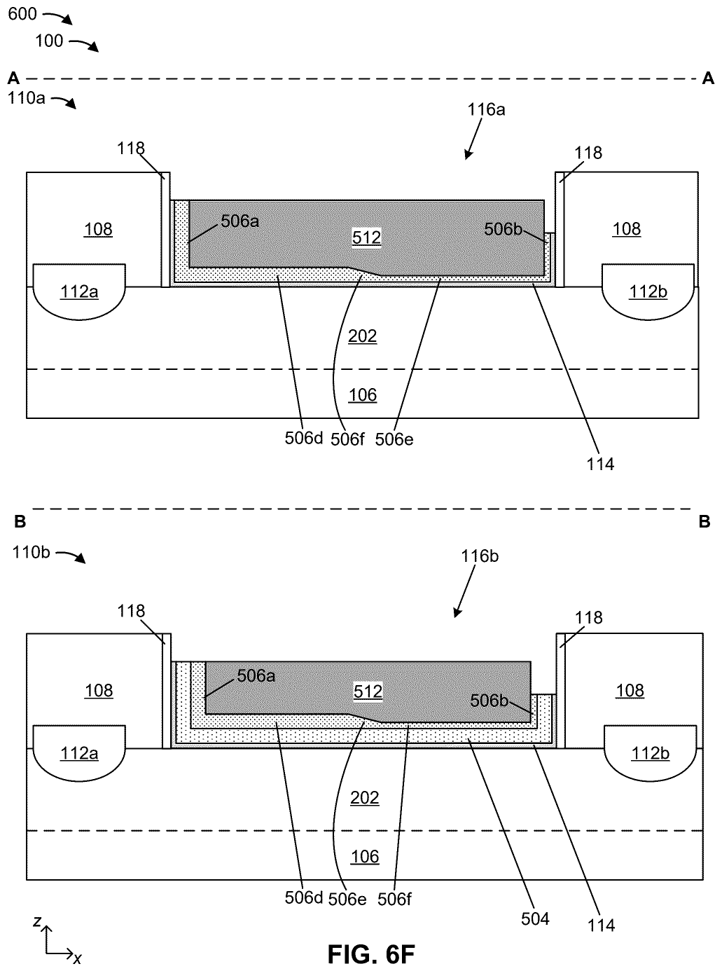

In some implementations, a difference between the vertical thickness of the bottom segment 506d of the n-type work function metal layer 506 (dimension D4) and the vertical thickness of the bottom segment 506e of the n-type work function metal layer 506 (dimension D7) may be included in a range of approximately 12 angstroms to approximately 42 angstroms. If the difference is less than approximately 12 angstroms, the vertical height of the sidewall segment 506b may not be sufficiently reduced in a subsequent gate trimming process described in connection with FIGS. 6A-6T to achieve a sufficiently low GIDL for the integrated circuit device 110a. If the difference is greater than approximately 42 angstroms, the vertical height of the sidewall segment 506b may be reduced by too great of an amount, which may increase the likelihood of gate-to-drain shorting in the integrated circuit device 110a and/or may reduce the breakdown voltage of the integrated circuit device 110a. However, other values and ranges other than approximately 12 angstroms to approximately 42 angstroms for the difference between the vertical thickness of the bottom segment 506d of the n-type work function metal layer 506 and the vertical thickness of the bottom segment 506e of the n-type work function metal layer 506 are within the scope of the present disclosure.

In some implementations, a lateral width of the transition segment 506f (indicated n FIG. 5P as dimension D8) may be included in a range of approximately 12 angstroms to approximately 42 angstroms. If the lateral width of the transition segment 506f is less than approximately 12 angstroms, the vertical height of the sidewall segment 506b may not be sufficiently reduced in a subsequent gate trimming process described in connection with FIGS. 6A-6T to achieve a sufficiently low GIDL for the integrated circuit device 110a. If the lateral width of the transition segment 506f is greater than approximately 42 angstroms, the vertical height of the sidewall segment 506b may be reduced by too great of an amount, which may increase the likelihood of gate-to-drain shorting in the integrated circuit device 110a and/or may reduce the breakdown voltage of the integrated circuit device 110a. However, other values and ranges other than approximately 12 angstroms to approximately 42 angstroms for the lateral width of the transition segment 506f are within the scope of the present disclosure.

As further shown in FIG. 5P, the sidewall segment 506a of the n-type work function metal layer 506 of the n-type gate structure 116a facing the source/drain region 112a remains at the initial lateral thickness (e.g., the dimension D6). However, the sidewall segment 506b of the n-type work function metal layer 506 of the n-type gate structure 116a facing the source/drain region 112b has a lateral thickness (indicated in FIG. 5P as dimension D9) that is less than the lateral thickness of the sidewall segment 506a. The lesser lateral thickness of the sidewall segment 506b enables the vertical height of the sidewall segment 506b to be reduced at a faster rate than the vertical height of the sidewall segment 506a in a subsequent gate trimming process described in connection with FIGS. 6A-6T.

As further shown in FIG. 5P, a bottom segment 506d of the n-type work function metal layer 506 of the p-type gate structure 116b under the masking layer 510 remains at the initial vertical thickness (e.g., the dimension D4). However, another bottom segment 506e of the n-type work function metal layer 506 of the p-type gate structure 116b that is exposed through the masking layer 510 has a vertical (z-direction) thickness (indicated in FIG. 5P as dimension D10) that is less than the vertical thickness of the bottom segment 506d. A transition segment 506f of the n-type work function metal layer 506 of the p-type gate structure 116b is located between the bottom segments 506d and 506e. The transition segment 506f may have a non-uniform vertical (z-direction) thickness. In the transition segment 506f, the vertical (z-direction) thickness transitions between the vertical thickness of the bottom segment 506d and the vertical thickness of the bottom segment 506e. In some implementations, the transition segment 506f has a sloped top surface such that the vertical thickness of the transition segment 506f gradually and substantially uniformly decreases from the bottom segment 506d to the bottom segment 506e. Alternatively, the transition segment 506f may have a stepped top surface or another top surface profile.

In some implementations, a difference between the vertical thickness of the bottom segment 506d of the n-type work function metal layer 506 (dimension D4) and the vertical thickness of the bottom segment 506e of the n-type work function metal layer 506 (dimension D10) may be included in a range of approximately 12 angstroms to approximately 42 angstroms. If the difference is less than approximately 12 angstroms, the vertical height of the sidewall segment 506b may not be sufficiently reduced in a subsequent gate trimming process described in connection with FIGS. 6A-6T to achieve a sufficiently low GIDL for the integrated circuit device 110b. If the difference is greater than approximately 42 angstroms, the vertical height of the sidewall segment 506b may be reduced by too great of an amount, which may increase the likelihood of gate-to-drain shorting in the integrated circuit device 110b and/or may reduce the breakdown voltage of the integrated circuit device 110b. However, other values and ranges other than approximately 12 angstroms to approximately 42 angstroms for the difference between the vertical thickness of the bottom segment 506d of the n-type work function metal layer 506 and the vertical thickness of the bottom segment 506e of the n-type work function metal layer 506 are within the scope of the present disclosure.

In some implementations, a lateral width of the transition segment 506f (indicated n FIG. 5P as dimension D11) may be included in a range of approximately 12 angstroms to approximately 42 angstroms. If the lateral width of the transition segment 506f is less than approximately 12 angstroms, the vertical height of the sidewall segment 506b may not be sufficiently reduced in a subsequent gate trimming process described in connection with FIGS. 6A-6T to achieve a sufficiently low GIDL for the integrated circuit device 110b. If the lateral width of the transition segment 506f is greater than approximately 42 angstroms, the vertical height of the sidewall segment 506b may be reduced by too great of an amount, which may increase the likelihood of gate-to-drain shorting in the integrated circuit device 110b and/or may reduce the breakdown voltage of the integrated circuit device 110b. However, other values and ranges other than approximately 12 angstroms to approximately 42 angstroms for the lateral width of the transition segment 506f are within the scope of the present disclosure.

As further shown in FIG. 5P, the sidewall segment 506a of the n-type work function metal layer 506 of the p-type gate structure 116b facing the source/drain region 112a remains at the initial lateral thickness (e.g., the dimension D6). However, the sidewall segment 506b of the n-type work function metal layer 506 of the p-type gate structure 116b facing the source/drain region 112b has a lateral thickness (indicated in FIG. 5P as dimension D12) that is less than the lateral thickness of the sidewall segment 506a. The lesser lateral thickness of the sidewall segment 506b enables the vertical height of the sidewall segment 506b to be reduced at a faster rate than the vertical height of the sidewall segment 506a in a subsequent gate trimming process described in connection with FIGS. 6A-6T.

The remaining portions of the masking layer 510 may be removed from the semiconductor device 100 after removing the portion of the n-type work function metal layer 506 from the n-type gate structure 116a. In some implementations, a photoresist removal tool is used to remove the remaining portions of the masking layer 508 (e.g., using a chemical stripper, plasma ashing, etching, and/or another technique).

As shown in FIGS. 5Q and 5R, the recesses 502 may be filled in with a gate electrode 512. The gate electrode 512 of the n-type gate structure 116a may be formed on the n-type work function metal layer 506 in the recess 502 between the source/drain regions 112a and 112b of the integrated circuit device 110a. The gate electrode 512 of the p-type gate structure 116b may be formed on the n-type work function metal layer 506 in the recess 502 between the source/drain regions 112a and 112b of the integrated circuit device 110b. The gate electrode 512 may overfill the recesses 502 and may be formed over the dielectric layer 108. Accordingly, a planarization tool may be used to perform a CMP operation or another type of planarization operation to planarize excess material of the gate electrode 512, the p-type work function metal layer 504, and the n-type work function metal layer 506 on the dielectric layer 108 so that the gate electrode 512, the p-type work function metal layer 504, and the n-type work function metal layer 506 are approximately co-planar with the top surface of the dielectric layer 108.

The gate electrode 512 includes one or more metal materials, such as ruthenium (Ru), tungsten (W), cobalt (Co), copper (Cu), and/or molybdenum (Mo), among other examples. A deposition tool may be used to deposit the gate electrode 512 using a CVD technique, a PVD technique, an ALD technique, an electroplating technique, and/or another suitable deposition technique. The gate electrode 512 may be deposited in one or more deposition operations. In some implementations, a seed layer is first deposited, and the gate electrode 512 is deposited on the seed layer.

As further shown in FIG. 5R, the bottom segment 506d of the n-type work function metal layer 506 is under a first portion of the gate electrode 512 of the n-type gate structure 116a, the bottom segment 506e of the n-type work function metal layer 506 is under a second portion of the gate electrode 512 of the n-type gate structure 116a, and the transition segment 506f of the n-type work function metal layer 506 is under a third portion of the gate electrode 512 of the n-type gate structure 116a. The bottom segment 506d is adjacent to the sidewall segment 506a of the n-type work function metal layer 506 of the n-type gate structure 116a, and the bottom segment 506e is adjacent to the sidewall segment 506b of the n-type work function metal layer 506 of the n-type gate structure 116a.

The bottom segment 506d of the n-type work function metal layer 506 is under a first portion of the gate electrode 512 of the p-type gate structure 116b, the bottom segment 506e of the n-type work function metal layer 506 is under a second portion of the gate electrode 512 of the p-type gate structure 116b, and the transition segment 506f of the n-type work function metal layer 506 is under a third portion of the gate electrode 512 of the p-type gate structure 116b. The bottom segment 506d is adjacent to the sidewall segment 506a of the n-type work function metal layer 506 of the p-type gate structure 116b, and the bottom segment 506e is adjacent to the sidewall segment 506b of the n-type work function metal layer 506 of the p-type gate structure 116b.

The sidewall segments 506a and 506b of the n-type work function metal layer 506 of the n-type gate structure 116a may each have approximately a z-direction height (dimension D13) after the planarization operation. The sidewall segments 504a and 504b of the p-type work function metal layer 504 may each have approximately a same z-direction height (dimension D13) after the planarization operation. The sidewall segments 506a and 506b of the n-type work function metal layer 506 of the p-type gate structure 116b may each have approximately a z-direction height (dimension D14) after the planarization operation.

As indicated above, FIGS. 5A-5R are provided as an example. Other examples may differ from what is described with regard to FIGS. 5A-5R.

FIGS. 6A-6F are diagrams of an example implementation 600 of a gate trimming process for high-voltage transistors in the device layer 102 of the semiconductor device 100 described herein. In some implementations, one or more of the semiconductor processing operations described in connection with FIGS. 6A-6F may be performed after one or more of the semiconductor processing operations described in connection with FIGS. 2A, 2B, 3, 4A-4D, and/or 5A-5R.

As shown in FIGS. 6A and 6B, the sidewall segments 506a and 506b of the n-type work function metal layer 506 of the n-type gate structure 116a, and the sidewall segments 506a and 506b of the n-type work function metal layer 506 of the p-type gate structure 116b may be etched in the gate trimming process. The p-type work function metal layer 504 of the p-type gate structure 116b may also be etched in a similar manner. In some implementations, a break through operation may be performed to etch, planarize, and/or otherwise remove a surface oxide layer from the n-type gate structure 116a and from the p-type gate structure 116b to enable the gate trimming process to be performed.

In some implementations, an etch tool is used to perform a wet etch to etch the sidewall segments 506a and 506b in the gate trimming process. A wet etchant may be provided on the sidewall segments 506a and 506b, and the wet etchant may selectively etch the sidewall segments 506a and 506b with minimal to no etching of the gate electrodes 512 and the gate dielectric layer 114 of the n-type gate structure 116a and the p-type gate structure 116b. However, other etch techniques, including gas-based etch techniques and/or plasma-based etch techniques, are within the scope of the present disclosure.

As shown in FIG. 6B, this results in the vertical (z-direction) height of the sidewall segments 506a and 506b of the n-type work function metal layer 506 of the n-type gate structure 116a being reduced (e.g., from the dimension D13 to a dimension D15). Because the lateral thickness of the sidewall segment 506b is less than the lateral thickness of the sidewall segment 506a, the vertical height of the sidewall segment 506b is reduced at a faster rate in the gate trimming process than the vertical height of the sidewall segment 506a (since there is less material to remove from the sidewall segment 506b). The faster reduction in vertical height of the sidewall segment 506b results in the vertical height of the sidewall segment 506b (indicated in FIG. 6B as dimension D16) being less than the vertical height of the sidewall segment 506a (e.g., D16<D15). The lower height of the sidewall segment 506b of the n-type work function metal layer 506 on the sidewall of the n-type gate structure 116a facing the source/drain region 112b enables less encroachment of a depletion region in the substrate layer 106 to be achieved for the source/drain region 112b, which reduces the amount of and/or likelihood of electron tunneling (and thus, off-current leakage) that might otherwise occur due to GIDL in the integrated circuit device 110a, and enables a low gate-to-drain parasitic capacitance (C_{gd}) to be achieved for the integrated circuit device 110a.

In some implementations, the vertical height of the sidewall segment 506a of the n-type work function metal layer 506 (dimension D15) after the gate trimming operation may be included in a range of approximately 86 angstroms to approximately 186 angstroms. Vertical height values of less than approximately 86 angstroms for the sidewall segment 506a may result in high gate resistance (R_{g}) for the n-type gate structure 116a. Vertical height values of greater than approximately 186 angstroms for the sidewall segment 506a may result in high gate-drain parasitic capacitance (C_{gd}) and/or increased likelihood of the n-type gate structure 116a shorting to a source/drain contact 120. However, other values and ranges other than approximately 86 angstroms to approximately 186 angstroms for the vertical height of the sidewall segment 506a are within the scope of the present disclosure.

In some implementations, the vertical height of the sidewall segment 506b of the n-type work function metal layer 506 (dimension D16) after the gate trimming operation may be included in a range of approximately 46 angstroms to approximately 146 angstroms. Vertical height values of less than approximately 46 angstroms for the sidewall segment 506b may result in high gate resistance (R_{g}) for the n-type gate structure 116a. Vertical height values of greater than approximately 146 angstroms for the sidewall segment 506b may result in high gate-drain parasitic capacitance (C_{gd}) and/or increased likelihood of the n-type gate structure 116a shorting to a source/drain contact 120. However, other values and ranges other than approximately 46 angstroms to approximately 146 angstroms for the vertical height of the sidewall segment 506b are within the scope of the present disclosure.

In some implementations, a difference between the height of the top surface of the sidewall segment 506a and the height of the top surface of the sidewall segment 506b (indicated in FIG. 6B as dimension D17) may be included in a range of approximately 40 angstroms to approximately 140 angstroms. If the difference between the height of the top surface of the sidewall segment 506a and the height of the top surface of the sidewall segment 506b is less than approximately 40 angstroms, the height of the top surface of the sidewall segment 506b may not be sufficiently low in order to achieve a low GIDL in the integrated circuit device 110a. If the difference between the height of the top surface of the sidewall segment 506a and the height of the top surface of the sidewall segment 506b is greater than approximately 140 angstroms, a likelihood of gate-to-drain shorting in the integrated circuit device 110a may be increased and/or the breakdown voltage of the integrated circuit device 110a may be reduced. However, other values and ranges other than approximately 40 angstroms to approximately 140 angstroms for the difference between the height of the top surface of the sidewall segment 506a and the height of the top surface of the sidewall segment 506b are within the scope of the present disclosure.

As further shown in FIG. 6B, the vertical (z-direction) height of the sidewall segments 506a and 506b of the n-type work function metal layer 506 of the p-type gate structure 116b may be reduced (e.g., from the dimension D14 to a dimension D18). The vertical height of the segment of the p-type work function metal layer 504 between the sidewall segment 506a and the gate dielectric layer 114 of the p-type gate structure 116b may also be reduced (e.g., from the dimension D13 to a dimension D19).

Because the lateral thickness of the sidewall segment 506b is less than the lateral thickness of the sidewall segment 506a, the vertical height of the sidewall segment 506b is reduced at a faster rate in the gate trimming process than the vertical height of the sidewall segment 506a (e.g., because there is less material to remove from the sidewall segment 506b). The faster reduction in vertical height of the sidewall segment 506b results in the vertical height of the sidewall segment 506b (indicated in FIG. 6B as dimension D20) being less than the vertical height of the sidewall segment 506a (e.g., D20<D18). The lower height of the sidewall segment 506b of the n-type work function metal layer 506 on the sidewall of the p-type gate structure 116b facing the source/drain region 112b enables less encroachment of a depletion region in the substrate layer 106 to be achieved for the source/drain region 112b, which reduces the amount of and/or likelihood of electron tunneling (and thus, off-current leakage) that might otherwise occur due to GIDL in the integrated circuit device 110b and enables a low gate-to-drain parasitic capacitance (C_{gd}) to be achieved for the integrated circuit device 110b. The vertical height of the segment of the p-type work function metal layer 504 between the sidewall segment 506b and the gate dielectric layer 114 of the p-type gate structure 116b may also be reduced (e.g., from the dimension D14 to a dimension D21).

In some implementations, the vertical height of the sidewall segment 506a of the n-type work function metal layer 506 (dimension D18) after the gate trimming operation may be included in a range of approximately 86 angstroms to approximately 186 angstroms. Vertical height values of less than approximately 86 angstroms for the sidewall segment 506a may result in high gate resistance (R_{g}) for the p-type gate structure 116b. Vertical height values of greater than approximately 186 angstroms for the sidewall segment 506a may result in high gate-drain parasitic capacitance (C_{gd}) and/or increased likelihood of the p-type gate structure 116b shorting to a source/drain contact 120. However, other values and ranges other than approximately 86 angstroms to approximately 186 angstroms for the vertical height of the sidewall segment 506a are within the scope of the present disclosure.

In some implementations, the vertical height of the sidewall segment 506b of the n-type work function metal layer 506 (dimension D20) after the gate trimming operation may be included in a range of approximately 46 angstroms to approximately 146 angstroms. Vertical height values of less than approximately 46 angstroms for the sidewall segment 506b may result in high gate resistance (R_{g}) for the p-type gate structure 116b. Vertical height values of greater than approximately 146 angstroms for the sidewall segment 506b may result in high gate-drain parasitic capacitance (C_{gd}) and/or increased likelihood of the p-type gate structure 116b shorting to a source/drain contact 120. However, other values and ranges other than approximately 46 angstroms to approximately 146 angstroms for the vertical height of the sidewall segment 506b are within the scope of the present disclosure.

In some implementations, a difference between the height of the top surface of the sidewall segment 506a and the height of the top surface of the sidewall segment 506b (indicated in FIG. 6B as dimension D22) may be included in a range of approximately 40 angstroms to approximately 140 angstroms. If the difference between the height of the top surface of the sidewall segment 506a and the height of the top surface of the sidewall segment 506b is less than approximately 40 angstroms, the height of the top surface of the sidewall segment 506b may not be sufficiently low in order to achieve a low GIDL in the integrated circuit device 110b. If the difference between the height of the top surface of the sidewall segment 506a and the height of the top surface of the sidewall segment 506b is greater than approximately 140 angstroms, a likelihood of gate-to-drain shorting in the integrated circuit device 110b may be increased and/or the breakdown voltage of the integrated circuit device 110b may be reduced. However, other values and ranges other than approximately 40 angstroms to approximately 140 angstroms for the difference between the height of the top surface of the sidewall segment 506b and the height of the top surface of the sidewall segment 506b are within the scope of the present disclosure.

As shown in FIGS. 6C and 6D, the gate trimming process may include trimming of portions of the gate dielectric layer 114 on the sidewalls of the n-type gate structure 116a and portions of the gate dielectric layer 114 on sidewalls of the p-type gate structure 116b. In some implementations, an etch tool is used to perform a wet etch to etch the portions of the gate dielectric layer 114 on the sidewalls of the n-type gate structure 116a and the portions of the gate dielectric layer 114 on sidewalls of the p-type gate structure 116b. A wet etchant may be provided on the portions of the gate dielectric layer 114 on the sidewalls of the n-type gate structure 116a and on the portions of the gate dielectric layer 114 on sidewalls of the p-type gate structure 116b. The wet etchant may selectively etch the gate dielectric layer 114 with minimal to no etching of the p-type work function metal layer 504, the n-type work function metal layer 506, and the gate electrodes 512. However, other etch techniques, including gas-based etch techniques and/or plasma-based etch techniques, are within the scope of the present disclosure.

As shown in FIG. 6D, the vertical heights of the portions of the gate dielectric layer 114 on the sidewalls of the n-type gate structure 116a are reduced. The top surface of the portion of the gate dielectric layer 114 between the dielectric layer 108 and the sidewall segment 506a, and the top surface of the sidewall segment 506a, may be approximately co-planar. The top surface of the portion of the gate dielectric layer 114 between the dielectric layer 108 and sidewall segment 506b, and the top surface of the sidewall segment 506b, may be approximately co-planar. Thus, the vertical heights of the portions of the gate dielectric layer 114 on the sidewalls of the n-type gate structure 116a are also uneven in that the vertical height (indicated in FIG. 6D as dimension D23) of the portion of the gate dielectric layer 114 facing the source/drain region 112b is less than the vertical height (indicated in FIG. 6D as dimension D24) of the portion of the gate dielectric layer 114 facing the source/drain region 112a. In some implementations, a ratio of the dimension D24 to the dimension D23 is included in a range of approximately 1.9:1 to approximately 4:1. However, other values and ranges are within the scope of the present disclosure.

As further shown in FIG. 6D, the vertical heights of the portions of the gate dielectric layer 114 on the sidewalls of the p-type gate structure 116b are reduced. The top surface of the portion of the gate dielectric layer 114 between the dielectric layer 108 and the sidewall segment 506a, and the top surface of the sidewall segment 506a, may be approximately co-planar. The top surface of the portion of the gate dielectric layer 114 between the dielectric layer 108 and sidewall segment 506b, and the top surface of the sidewall segment 506b, may be approximately co-planar. Thus, the vertical heights of the portions of the gate dielectric layer 114 on the sidewalls of the p-type gate structure 116b are also uneven in that the vertical height (indicated in FIG. 6D as dimension D25) of the portion of the gate dielectric layer 114 facing the source/drain region 112b is less than the vertical height (indicated in FIG. 6D as dimension D26) of the portion of the gate dielectric layer 114 facing the source/drain region 112a.

In some implementations, a difference between the height of the top surface of the portion of the gate dielectric layer 114 on the sidewall of the n-type gate structure 116a facing the source/drain region 112a of the integrated circuit device 110a and the height of the top surface of the portion of the gate dielectric layer 114 on the sidewall of the n-type gate structure 116a facing the source/drain region 112b of the integrated circuit device 110a (indicated in FIG. 6D as dimension D27) may be included in a range of approximately 40 angstroms to approximately 140 angstroms. If the difference in height is less than approximately 40 angstroms, the height of the portion of the gate dielectric layer 114 facing the source/drain region 112b may not be sufficiently low in order to achieve a low GIDL in the integrated circuit device 110a. If the difference in height is greater than approximately 140 angstroms, a likelihood of gate-to-drain shorting in the integrated circuit device 110a may be increased and/or the breakdown voltage of the integrated circuit device 110a may be reduced. However, other values and ranges other than approximately 40 angstroms to approximately 140 angstroms for the difference in height are within the scope of the present disclosure.

In some implementations, a difference between the height of the top surface of the portion of the gate dielectric layer 114 on the sidewall of the p-type gate structure 116b facing the source/drain region 112a of the integrated circuit device 110b and the height of the top surface of the portion of the gate dielectric layer 114 on the sidewall of the p-type gate structure 116b facing the source/drain region 112b of the integrated circuit device 110b (indicated in FIG. 6D as dimension D28) may be included in a range of approximately 40 angstroms to approximately 140 angstroms. If the difference in height is less than approximately 40 angstroms, the height of the portion of the gate dielectric layer 114 facing the source/drain region 112b may not be sufficiently low in order to achieve a low GIDL in the integrated circuit device 110b. If the difference in height is greater than approximately 140 angstroms, a likelihood of gate-to-drain shorting in the integrated circuit device 110b may be increased and/or the breakdown voltage of the integrated circuit device 110b may be reduced. However, other values and ranges other than approximately 40 angstroms to approximately 140 angstroms for the difference in height are within the scope of the present disclosure.

As shown in FIGS. 6E and 6F, the gate trimming process may include trimming of the gate electrodes 512 of the n-type gate structure 116a and of the p-type gate structure 116b. In some implementations, an etch tool is used to perform a wet etch to etch the gate electrodes 512. A wet etchant may be provided on the gate electrodes 512, and the wet etchant may selectively etch the gate electrodes 512 with minimal to no etching of the p-type work function metal layer 504, the n-type work function metal layer 506, and the gate dielectric layer 114. However, other etch techniques, including gas-based etch techniques and/or plasma-based etch techniques, are within the scope of the present disclosure.

As further shown in FIG. 6F, the top surface of the gate electrode 512 of the n-type gate structure 116a may be approximately co-planar with a top surface of the sidewall segment 506a of the n-type work function metal layer 506. The top surface of the gate electrode 512 of the n-type gate structure 116a may higher than a top surface of the sidewall segment 506b of the type work function metal layer 506. The top surface of the gate electrode 512 of the p-type gate structure 116b may be approximately co-planar with a top surface of the sidewall segment 506a of the n-type work function metal layer 506. The top surface of the gate electrode 512 of the p-type gate structure 116b may higher than a top surface of the sidewall segment 506b of the n-type work function metal layer 506.

As indicated above, FIGS. 6A-6F are provided as an example. Other examples may differ from what is described with regard to FIGS. 6A-6F.

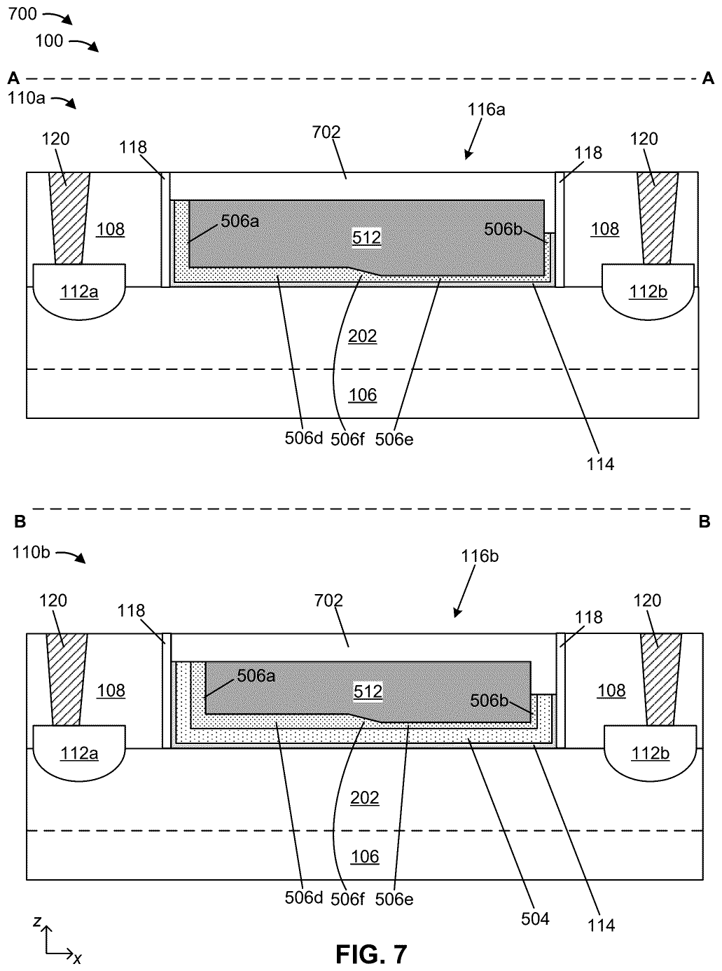

FIG. 7 is a diagram of an example implementation 700 of a contact formation process for high-voltage transistors in the device layer 102 of the semiconductor device 100 described herein. In some implementations, one or more of the semiconductor processing operations described in connection with FIG. 7 may be performed after one or more of the semiconductor processing operations described in connection with FIGS. 2A, 2B, 3, 4A-4D, 5A-5R, and/or 6A-6F.

As shown in FIG. 7, a capping layer 702 may be formed over the n-type gate structure 116a of the integrate circuit device 110a (e.g., the NMOS high-voltage transistor) and over the p-type gate structure 116b of the integrate circuit device 110b (e.g., the PMOS high-voltage transistor). A deposition tool may be used to deposit the capping layer 702 using a CVD technique, a PVD technique, an ALD technique, an oxidation technique, and/or another suitable deposition technique. In some implementations, a planarization tool is used to perform a planarization operation (e.g., a CMP operation) to planarize the capping layer 702 after the capping layer 702 is deposited.

As further shown in FIG. 7, source/drain contacts 120 may be formed through the dielectric layer 108 and on the source/drain regions 112a and 112b of the integrated circuit devices 110a and 110b. The source/drain regions 112a and 112b may be formed in recesses in the dielectric layer 108. For example, recesses may be formed over the source/drain regions 112a and 112b, and the source/drain contacts 120 may be formed in the recesses such that the source/drain contacts 120 land on the source/drain regions 112a and 112b.

In some implementations, a pattern in a photoresist layer is used to form the recesses in the dielectric layer 108. In these implementations, a deposition tool may be used to form the photoresist layer over the dielectric layer 108. An exposure tool may be used to expose the photoresist layer to a radiation source to pattern the photoresist layer. A developer tool may be used to develop and remove portions of the photoresist layer to expose the pattern. An etch tool may be used to etch through the dielectric layer 108 to form the recesses. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses based on a pattern.

A deposition tool may be used to deposit the source/drain contacts 120 in the recesses using a CVD technique, a PVD technique, an ALD technique, an electroplating technique, and/or another suitable deposition technique. The source/drain contacts 120 may be deposited in one or more deposition operations. In some implementations, a seed layer is first deposited, and the source/drain contacts 120 are deposited on the seed layer. In some implementations, a liner layer 122 is deposited in the recesses, and the source/drain contacts 120 are deposited on the liner layer 122 in the recesses. The liner layer 122 may include a barrier liner, an adhesion liner, and/or another suitable liner. Examples of liner materials include tantalum nitride (TaN), titanium nitride (TiN), and/or other suitable liner materials. In some implementations, a planarization tool is used to perform a planarization operation (e.g., a CMP operation) to planarize the source/drain contacts 120 after the source/drain contacts 120 are deposited.

As indicated above, FIG. 7 is provided as an example. Other examples may differ from what is described with regard to FIG. 7.

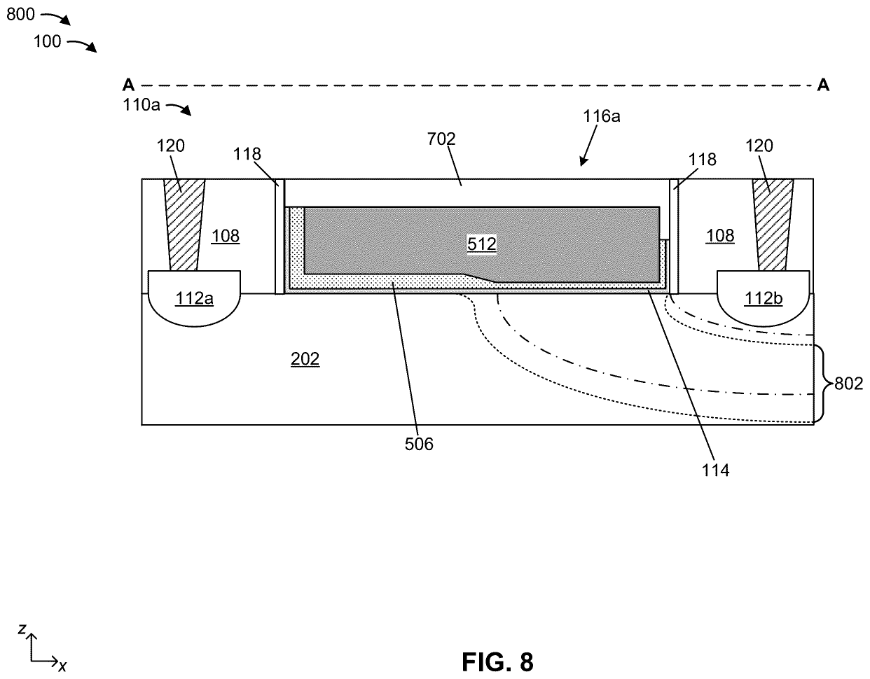

FIG. 8 is a diagram of an example 800 of a depletion region of a high-voltage transistor of the semiconductor device 100 described herein. In particular, the example 800 includes an example of a depletion region 802 of the integrated circuit device 110a (e.g., the NMOS high-voltage transistor) that results from the lower height of the gate dielectric layer 114 and the lower height of the n-type work function metal layer 506 on the sidewall of the n-type gate structure 116a facing the source/drain region 112b.

As shown in FIG. 8, the depletion region 802 does not encroach on (and does not overlap with) the source/drain region 112b. The spacing between the depletion region 802 and the source/drain region 112b reduces the amount of and/or likelihood of electron tunneling (and thus, off-current leakage) that might otherwise occur due to GIDL in the integrated circuit device 110a. Thus, the lower height of the gate dielectric layer 114 and the lower height of the n-type work function metal layer 506 on the sidewall of the n-type gate structure 116a facing the source/drain region 112b increases the operating efficiency of the integrated circuit device 110a and reduces the power consumption of the integrated circuit device 110a.

Additionally and/or alternatively, the spacing between the depletion region 802 and the source/drain region 112b enables a low gate-to-drain parasitic capacitance (C_{gd}) to be achieved for the integrated circuit device 110a in that the spacing between the depletion region 802 and the source/drain region 112b provides for a low amount parasitic capacitance due to gate-drain overlap (Cₒᵥ). Thus, the lower height of the gate dielectric layer 114 and the lower height of the n-type work function metal layer 506 on the sidewall of the n-type gate structure 116a facing the source/drain region 112b reduces the RC delay of the n-type gate structure 116a, which enables faster switching to be achieved for the n-type gate structure 116a.

As indicated above, FIG. 8 is provided as an example. Other examples may differ from what is described with regard to FIG. 8.

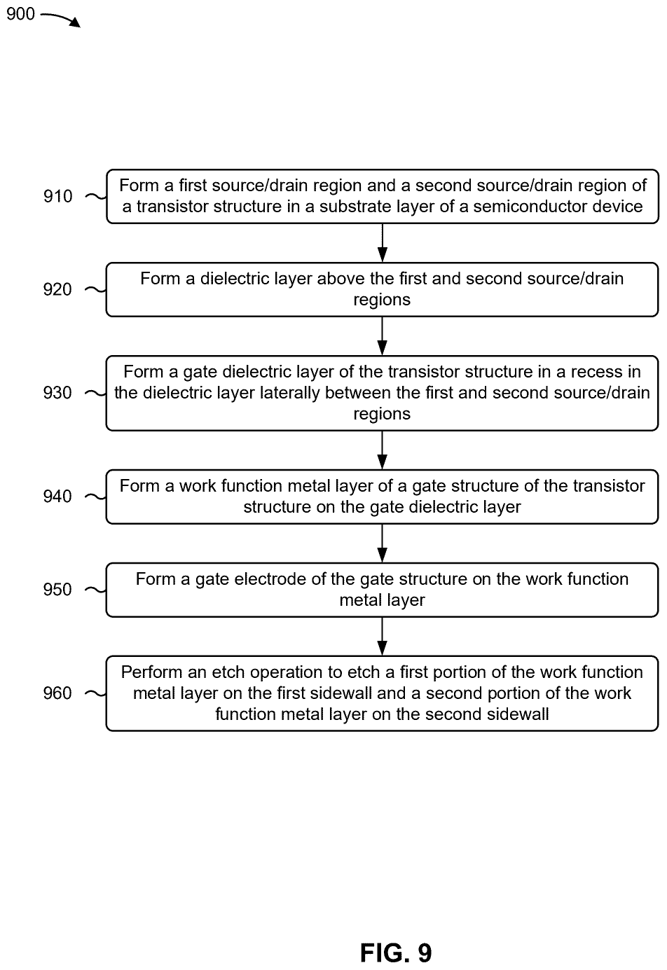

FIG. 9 is a flowchart of an example process 900 associated with forming a semiconductor device described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include forming a first source/drain region and a second source/drain region of a transistor structure in a substrate layer of a semiconductor device (block 910). For example, one or more semiconductor processing tools may be used to form a first source/drain region (e.g., a source/drain region 112a) and a second source/drain region (e.g., a source/drain region 112b) of a transistor structure (e.g., an integrated circuit device 110, an integrated circuit device 110a, an integrated circuit device 110b) in a substrate layer (e.g., a substrate layer 106) of a semiconductor device (e.g., semiconductor device 100), as described herein.

As further shown in FIG. 9, process 900 may include forming a dielectric layer above the first and second source/drain regions (block 920). For example, one or more semiconductor processing tools may be used to form a dielectric layer (e.g., a dielectric layer 108) above the first and second source/drain regions, as described herein.

As further shown in FIG. 9, process 900 may include forming a gate dielectric layer of the transistor structure in a recess in the dielectric layer laterally between the first and second source/drain regions (block 930). For example, one or more semiconductor processing tools may be used to form a gate dielectric layer (e.g., a gate dielectric layer 114) of the transistor structure in a recess (e.g., a recess 502) in the dielectric layer laterally between the first and second source/drain regions, as described herein. In some implementations, the gate dielectric layer is formed on a first sidewall, a second sidewall, and a bottom surface of the recess.

As further shown in FIG. 9, process 900 may include forming a work function metal layer of a gate structure of the transistor structure on the gate dielectric layer (block 940). For example, one or more semiconductor processing tools may be used to form a work function metal layer (e.g., an n-type work function metal layer 506, a p-type work function metal layer 504) of a gate structure (e.g., a gate structure 116, an n-type gate structure 116a, a p-type gate structure 116b) of the transistor structure on the gate dielectric layer, as described herein.

As further shown in FIG. 9, process 900 may include forming a gate electrode (512) of the gate structure on the work function metal layer (block 950). For example, one or more semiconductor processing tools may be used to form a gate electrode (e.g., a gate electrode 512) of the gate structure on the work function metal layer, as described herein.

As further shown in FIG. 9, process 900 may include performing an etch operation to etch a first portion of the work function metal layer on the first sidewall and a second portion of the work function metal layer on the second sidewall (block 960). For example, one or more semiconductor processing tools may be used to perform an etch operation to etch a first portion of the work function metal layer on the first sidewall and a second portion of the work function metal layer on the second sidewall, as described herein. In some implementations, a first vertical height (e.g., a dimension D15, a dimension D18, a dimension D19) of the first portion of the work function metal layer and a second vertical height (e.g., a dimension D16, a dimension D20, a dimension D21) of the second portion of the work function metal layer are different vertical heights after the etch operation.

Process 900 may include additional implementations, such as any single implementation or any combination of implementations described below and/or in connection with one or more other processes described elsewhere herein.

In a first implementation, the first vertical height of the first portion of the work function metal layer is greater than the second vertical height of the second portion of the work function metal layer after the etch operation.

In a second implementation, alone or in combination with the first implementation, process 900 includes performing another etch operation to etch the second portion of the work function metal layer on the second sidewall prior to forming the gate electrode, where a first lateral thickness (e.g., a dimension D3, a dimension D6) of the first portion of the work function metal layer is greater than a second lateral thickness (e.g., a dimension D8, a dimension D12) of the second portion of the work function metal layer after the other etch operation.

In a third implementation, alone or in combination with one or more of the first and second implementations, performing the other etch operation comprises performing the other etch operation to etch the second portion of the work function metal layer on the second sidewall while a masking layer (e.g., a masking layer 510) protects the first portion of the work function metal layer on the first sidewall.

In a fourth implementation, alone or in combination with one or more of the first through third implementations, process 900 includes performing another etch operation to etch a third portion of the gate dielectric layer on the first sidewall and a fourth portion of the gate dielectric layer on the second sidewall, where a third vertical height (e.g., a dimension D24, a dimension D26) of the third portion of the gate dielectric layer and a fourth vertical height (e.g., a dimension D23, a dimension D25) of the fourth portion of the gate dielectric layer are different vertical heights after the other etch operation.

In a fifth implementation, alone or in combination with one or more of the first through fourth implementations, the third vertical height of the third portion of the gate dielectric layer is greater than the fourth vertical height of the fourth portion of the gate dielectric layer after the other etch operation.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, a high-voltage transistor includes an asymmetric gate dielectric layer and a gate structure that includes one or more asymmetric work function metal layers. The gate dielectric layer and the work function metal layer(s) are asymmetric in that the height of the gate dielectric layer and the height of the work function metal layer(s) on opposing sides of the gate structure are different. In particular, the height of the gate dielectric layer and the height of the work function metal layer(s) on a side of the gate structure facing the drain region of the high-voltage transistor are lower than the height of the gate dielectric layer and the height of the work function metal layer(s) on an opposing side of the gate structure facing the source region of the high-voltage transistor. The lower heights of the gate dielectric layer and the work function metal layer(s) on the drain side of the gate structure reduces (or prevents) an overlap of a depletion region and the drain region, which reduces the amount of electron tunneling (and therefore, the amount of GIDL in the high-voltage transistor) as well as the amount of gate to drain overlap parasitic capacitance (Cₒᵥ) in the high-voltage transistor. Thus, the lower heights of the gate dielectric layer and the work function metal layer(s) on the drain side of the gate structure enables a low off-current leakage to be achieved for the high-voltage transistor, and enables faster switching speeds to be achieved for the high-voltage transistor (e.g., due to lower RC delay).

As described in greater detail above, some implementations described herein provide a semiconductor device. The semiconductor device includes a first source/drain region in a substrate layer of the semiconductor device. The semiconductor device includes a second source/drain region in the substrate layer. The semiconductor device includes a gate structure laterally between the first source/drain region and the second source/drain region. The gate structure includes a gate electrode and a work function metal layer between the gate electrode and the substrate layer. A first segment of the work function metal layer extends along a first side of the gate electrode facing the first source/drain region. A second segment of the work function metal layer extends along a second side of the gate electrode facing the second source/drain region. A first height of the first segment of the work function metal layer is greater than a second height of the second segment of the work function metal layer.

As described in greater detail above, some implementations described herein provide a semiconductor device. The semiconductor device includes a first source/drain region in a substrate layer of the semiconductor device. The semiconductor device includes a second source/drain region in the substrate layer. The semiconductor device includes a gate structure laterally between the first source/drain region and the second source/drain region. The gate structure includes a gate electrode and a work function metal layer between the gate electrode and the substrate layer, and between the gate electrode and a dielectric layer above the substrate layer. The semiconductor device includes a gate dielectric layer between the work function metal layer and the substrate layer, and between the work function metal layer and the dielectric layer. A first segment of the gate dielectric layer extends along a first side of the gate electrode facing the first source/drain region. A second segment of the gate dielectric layer extends along a second side of the gate electrode facing the second source/drain region, and a first height of the first segment of the gate dielectric layer is greater than a second height of the second segment of the gate dielectric layer.

As described in greater detail above, some implementations described herein provide a method. The method includes forming a first source/drain region and a second source/drain region of a transistor structure in a substrate layer of a semiconductor device. The method (800) includes forming a dielectric layer above the first and second source/drain regions. The method includes forming a gate dielectric layer of the transistor structure in a recess in the dielectric layer laterally between the first and second source/drain regions, where the gate dielectric layer is formed on a first sidewall, a second sidewall, and a bottom surface of the recess. The method includes forming a work function metal layer of a gate structure of the transistor structure on the gate dielectric layer. The method includes forming a gate electrode of the gate structure on the work function metal layer. The method includes performing an etch operation to etch a first portion of the work function metal layer on the first sidewall and a second portion of the work function metal layer on the second sidewall, where a first vertical height of the first portion of the work function metal layer and a second vertical height of the second portion of the work function metal layer are different vertical heights after the etch operation.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first source/drain region in a substrate layer of the semiconductor device;
a second source/drain region in the substrate layer; and
a gate structure laterally between the first source/drain region and the second source/drain region, comprising:
a gate electrode; and
a work function metal layer between the gate electrode and the substrate layer,
wherein a first segment of the work function metal layer extends along a first side of the gate electrode facing the first source/drain region,
wherein a second segment of the work function metal layer extends along a second side of the gate electrode facing the second source/drain region, and
wherein a first height of the first segment of the work function metal layer is greater than a second height of the second segment of the work function metal layer.

2. The semiconductor device of claim 1, wherein the work function metal layer comprises:
a third segment under a first portion of the gate electrode,
wherein the third segment is adjacent to the first segment, and
wherein the third segment has a first thickness; and
a fourth segment under a second portion of the gate electrode,
wherein the fourth segment is adjacent to the second segment,
wherein the fourth segment has a second thickness, and
wherein the first thickness and the second thickness are different thicknesses.

3. The semiconductor device of claim 2, wherein the second thickness is less than the first thickness.

4. The semiconductor device of claim 2, wherein the work function metal layer comprises a transition segment laterally between the third segment and the fourth segment.

5. The semiconductor device of claim 4, wherein the transition segment has a non-uniform thickness that transitions between the first thickness and the second thickness.

6. The semiconductor device of claim 1, wherein the first segment has a first thickness;
wherein the second segment has a second thickness; and
wherein the first thickness and the second thickness are different thicknesses.

7. The semiconductor device of claim 6, wherein the second thickness is less than the first thickness.

8. A semiconductor device, comprising:
a first source/drain region in a substrate layer of the semiconductor device;
a second source/drain region in the substrate layer;
a gate structure, laterally between the first source/drain region and the second source/drain region, comprising:
a gate electrode; and
a work function metal layer between the gate electrode and the substrate layer, and between the gate electrode and a dielectric layer above the substrate layer; and
a gate dielectric layer between the work function metal layer and the substrate layer, and between the work function metal layer and the dielectric layer,
wherein a first segment of the gate dielectric layer extends along a first side of the gate electrode facing the first source/drain region,
wherein a second segment of the gate dielectric layer extends along a second side of the gate electrode facing the second source/drain region, and
wherein a first height of the first segment of the gate dielectric layer is greater than a second height of the second segment of the gate dielectric layer.

9. The semiconductor device of claim 8, wherein the work function metal layer comprises:
a third segment between the first side of the gate electrode and the first segment of the gate dielectric layer,
wherein the third segment has a first lateral thickness; and
a fourth segment between the second side of the gate electrode and the second segment of the gate dielectric layer,
wherein the fourth segment has a second lateral thickness, and
wherein the first lateral thickness and the second lateral thickness are different thicknesses.

10. The semiconductor device of claim 9, wherein the second lateral thickness is less than the first lateral thickness.

11. The semiconductor device of claim 9, wherein the third segment of the work function metal layer has a third height,
wherein the fourth segment of the work function metal layer has a fourth height; and
wherein the third height and the fourth height are different heights.

12. The semiconductor device of claim 11, wherein the fourth height is less than the third height.

13. The semiconductor device of claim 11, wherein the fourth height of the fourth segment of the work function metal layer is less than the first height of the first segment of the gate dielectric layer.

14. The semiconductor device of claim 11, wherein the second height of the second segment of the gate dielectric layer is less than the third height of the third segment of the work function metal layer.

15. A method, comprising:
forming a first source/drain region and a second source/drain region of a transistor structure in a substrate layer of a semiconductor device;
forming a dielectric layer above the first and second source/drain regions;
forming a gate dielectric layer of the transistor structure in a recess in the dielectric layer laterally between the first and second source/drain regions,
wherein the gate dielectric layer is formed on a first sidewall, a second sidewall, and a bottom surface of the recess;
forming a work function metal layer of a gate structure of the transistor structure on the gate dielectric layer;
forming a gate electrode of the gate structure on the work function metal layer; and
performing an etch operation to etch a first portion of the work function metal layer on the first sidewall and a second portion of the work function metal layer on the second sidewall,
wherein a first vertical height of the first portion of the work function metal layer and a second vertical height of the second portion of the work function metal layer are different vertical heights after the etch operation.

16. The method of claim 15, wherein the first vertical height of the first portion of the work function metal layer is greater than the second vertical height of the second portion of the work function metal layer after the etch operation.

17. The method of claim 16, further comprising:
performing another etch operation to etch the second portion of the work function metal layer on the second sidewall prior to forming the gate electrode,
wherein a first lateral thickness of the first portion of the work function metal layer is greater than a second lateral thickness of the second portion of the work function metal layer after the other etch operation.

18. The method of claim 17, wherein performing the other etch operation comprises:
performing the other etch operation to etch the second portion of the work function metal layer on the second sidewall while a masking layer protects the first portion of the work function metal layer on the first sidewall.

19. The method of claim 15, further comprising:
performing another etch operation to etch a third portion of the gate dielectric layer on the first sidewall and a fourth portion of the gate dielectric layer on the second sidewall,
wherein a third vertical height of the third portion of the gate dielectric layer and a fourth vertical height of the fourth portion of the gate dielectric layer are different vertical heights after the other etch operation.

20. The method of claim 19, wherein the third vertical height of the third portion of the gate dielectric layer is greater than the fourth vertical height of the fourth portion of the gate dielectric layer after the other etch operation.
